(19) United States
(12) Patent Application Publication
(10) Pub. No.: US 2026/0297423 A1
(43) Pub. Date: Oct. 1, 2026

(54) COMPOSITION

(71) Applicant: SAMSUNG ELECTRONICS CO., LTD., Suwon-si (KR)

(72) Inventors: Elizaveta KOSSOY, Jerusalem (IL); Suzanna AZOUBEL, Jerusalem (IL); Gil BERNSTEIN TOKER, Jerusalem (IL); Hiromoto SATO, Kakegawa-shi (JP); Tadashi KISHIMOTO, Kakegawa-shi (JP); Tomohisa GOTO, Kakegawa-shi (JP); Teruaki SUZUKI, Kakegawa-shi (JP)

(73) Assignee: SAMSUNG ELECTRONICS CO., LTD., Suwon-si (KR)

(21) Appl. No.: 19/100,603

(22) PCT Filed: Aug. 3, 2023
(86) PCT No.: PCT/EP2023/071515

§ 371 Date: Feb. 3, 2025

(30) Foreign Application Priority Data
Aug. 5, 2022 (EP) 22189039.5

(51) Int. Cl. C09K 11/70; C08F 220/18; C09K 11/88; C09K 113/00; G02F 1/061; H10K 50/115; H10K 59/12; H10K 59/122; H10K 71/13; H10K 71/40

(52) U.S. Cl. CPC C09K 11/70; C08F 220/18; C09K 11/883; G02F 1/061; H10K 50/115; H10K 59/122; H10K 71/135; H10K 71/40; C09K 2113/00; H10K 59/1201

(57) ABSTRACT

The present invention relates to a composition containing a light emitting moiety such as quantum materials incl. quantum dots; and a process for fabricating the composition.

### FIELD OF THE INVENTION

The present invention relates to a composition containing a light emitting moiety; a process for fabricating the composition; formulation; use of a composition, method for forming a layer; a layer; a color conversion device; and an optical device.

### BACKGROUND ART

Light emitting nanoparticles are known in the prior art documents. For example, Turo et al., ACS NANO vol. 8, no. 10, 10205-10203, 2014 discloses Cu₂S Nanoparticles having no shell layers with dodecanethiol (DDT) and the fabrication process with using DDT at the temperature of 200° C. DDT is used in the entire synthesis process.

Turo et al., Chem Commun, 2016, 52, 12214-12217 describes CdSe/ZnS with dodecanethiol.

Robinson et al., Chem Mater, 2017, 29, 3854-3857 mentions quasi spherical Cu₂S nanorods with DDT.

### PATENT LITERATURE

No literature

### Non-Patent Literature

1. Turo et al., ACS NANO vol. 8, no. 10, 10205-10203, 2014
2. Chem Commun, 2016, 52, 12214-12217
3. Robinson et al., Chem Mater, 2017, 29, 3854-3857

### SUMMARY OF THE INVENTION

However, the inventors newly have found that there is still one or more of considerable problems for which improvement is desired, as listed below; realizing an optimized haze value of the cured layer (film), optimal haze value with improved EQE value of the cured layer (film), preferably obtaining optimal haze value with improved EQE value of the cured layer (film) without using scatting particle, improved thermal stability of an obtained layer (film), improved thermal stability of a light emitting moiety in a layer (film), improved dispersibility of a light emitting moiety in a composition, enabling a phase separation of light emitting moiety and matrix material after curing realizing an improved haze value of the cured film (cured composition), improved dispersibility of a light emitting moiety in an obtained layer, improved long term Quantum Yield (QY) stability of a light emitting moiety in the composition in a longer term storage with our without external light irradiation, improved long term External Quantum Efficiency (EQE) stability of a light emitting moiety in the composition in a longer term storage with our without external light irradiation, improved long term Quantum Yield (QY) stability of a light emitting moiety in the obtained layer (film) in a longer term storage with our without light external irradiation, improved long term External Quantum Efficiency (EQE) stability of a light emitting moiety in the obtained layer (film) in a longer term storage with our without external light irradiation, improved good compatibility of light emitting moiety with a matrix material in a composition and/or an obtained layer (film), and/or realizing easy handling of a composition containing a light emitting moiety and a matrix material, making composition suitable for inkjet printing.

The inventors aimed to solve one or more of the above-mentioned problems.

The present inventors have surprisingly found that one or more of the above described technical problems can be solved by the features as defined in the claims.

Namely, it was found a novel composition, preferably it is being of a photocurable composition, comprising at least, mainly consisting of, or consisting of;
i) a light emitting moiety, preferably it is a semiconducting light emitting nanoparticle, comprising an outer layer containing a metal cation and a divalent anion; and one or more types of organic moieties directly attached to the anion of the outer layer by covalent bond,
ii) at least one reactive monomer or a mixture of two or more reactive monomers, preferably said monomer having one or more of functional groups, more preferably it is a (meth)acrylate monomer;
wherein said divalent anion of the outer layer is selected from Se²⁻, S²⁻, Te²⁻O²⁻ or a combination of any of these, preferably said metal cation of the outer layer is a monovalent, divalent, trivalent or tetravalent cation, more preferably said metal cation is a divalent cation selected from the group consisting of Zn²⁺, Ni²⁺, Co²⁺, Ca²⁺, Sr²⁺, Hg²⁺, Mg²⁺ and Pb²⁺, or a tetravalent cation selected from the group consisting of Ti⁴⁺, Ge⁴⁺, Si⁴⁺, Zr⁴⁺Hf⁴⁺, and Sn⁴⁺.

In another aspect, the present invention further relates to a process for preparing the composition of the present invention comprising, mainly consisting of, or consisting of, at least following steps,
(a) mixing at least a semiconducting nanoparticle, preferably said semiconducting nanoparticle comprises at least a 1^{st} semiconducting nanomaterial as a core,
with another material to get a reaction mixture, preferably said another material is a solvent;
(b) forming an outer layer onto the semiconducting nanoparticle in the reaction mixture by reacting at least an anion source represented by chemical formula (Va) or chemical formula (Vb) with a metal cation precursor in a reaction mixture, in some embodiment of the present invention, said metal cation precursor can be the same to the cation shell precursor;

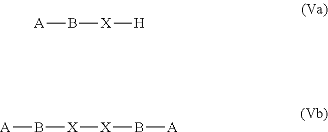

wherein
A is an organic group;
B is a connecting unit connecting A and X;
H is a hydrogen atom; and
X is an anchor group comprising an anion, capable to form a monolayer with the added metal cation derivable from the added metal cation precursor;
(c) cooling the reaction mixture from step (b),
wherein the reaction mixture in step (b) is kept at a temperature in the range from 80° C. to 200° C., preferably 100 to 200° C. to form the outer layer in step (b),
(d) mixing a light emitting moiety obtained from step (c) with at least one reactive monomer or a mixture of two or more reactive monomers to from a composition.

In another aspect, the present invention relates to a composition obtainable or obtained from the process of the present invention.

In another aspect, the present invention relates to formulation comprising, essentially consisting of, or consisting of, at least a composition of the present invention,
and at least one solvent, preferably the solvent is selected from one or more members of the group consisting of aromatic, halogenated and aliphatic hydrocarbon solvents, ethers, esters, ionic liquids, alcohols and water, more preferably selected from one or more members of the group consisting of toluene, xylene, tetrahydrofuran, chloroform, dichloromethane and heptane, hexane, purified water, ester acetates, ether acetates, ketones, etheric esters such as PGMEA, alcohols such as ethanol, isopropanol etc., sulfoxides, formamides, nitrides, ketones.

In another aspect, the present invention relates to use of the composition, or the formulation, in an electronic device, optical device, sensing device or a biomedical device.

In another aspect, the present invention relates to a method for forming a layer comprising:
S1) providing the composition of the present invention onto a substrate, preferably by ink-jetting;
S2) curing the composition, preferably said curing is a photo curing performed by photo irradiation, thermal curing or a combination of a photo curing and a thermal curing.

In another aspect, the present invention further relates to a layer obtained or obtainable from the method of the present invention.

In another aspect, the present invention further relates to a layer containing at least, mainly consisting of or consisting of;
Xi) a light emitting moiety, preferably it is a semiconducting light emitting nanoparticle, comprising an outer layer containing a metal cation and a divalent anion; and one or more types of organic moieties directly attached to the anion of the outer layer by covalent bond,
Xii) a polymer made from at least one reactive monomer or a mixture of two or more reactive monomers, preferably said monomer having one or more of functional groups, more preferably it is a(meth)acrylate monomer;
wherein said divalent anion of the outer layer is selected from Se²⁻, S²⁻, Te²⁻O²⁻ or a combination of any of these, preferably said metal cation of the outer layer is a monovalent, divalent, trivalent or tetravalent cation, more preferably said metal cation is a divalent cation selected from the group consisting of Zn²⁺, Ni²⁺, Co²⁺, Ca²⁺, Sr²⁺, Hg²⁺, Mg²⁺ and Pb²⁺, or a tetravalent cation selected from the group consisting of Ti⁴⁺, Ge⁴⁺, Si⁴⁺, Zr⁴⁺, Hf⁴⁺, and Sn⁴⁺.

In another aspect, the present invention further relates to a color conversion device (100) comprising at least a 1^{st} pixel (161) partly or fully filled with the layer of the present invention comprising at least a matrix material (120) containing a light emitting moiety (110), and a bank (150) comprising at least a polymer material, preferably the color conversion device (100) further contains a supporting medium (170).

In another aspect, the present invention further relates to an optical device (300) containing at least one functional medium (320, 420, 520) configured to modulate a light or configured to emit light, and the color conversion device (100) of the present invention.

### DESCRIPTION OF DRAWINGS

FIG. 1: shows a cross sectional view of a schematic of one embodiment of a color conversion film (100).

FIG. 2: shows a top view of a schematic of another embodiment of a color conversion film (100) of the invention.

FIG. 3: shows a cross sectional view of a schematic of one embodiment of an optical device (300) of the invention.

FIG. 4: shows a cross sectional view of a schematic of another embodiment of an optical device (300) of the invention.

FIG. 5: shows a cross sectional view of a schematic of another embodiment of an optical device (300) of the invention.

FIG. 6: ¹H NMR spectra (in toluene d8) of QDs from reference example 1 before (a) and after (b) addition of 3-phenylpropylphosphonic (PPPA).

FIG. 7: ¹H NMR spectrum (in toluene d8) of QDs from reference example 1 after treating with PPPA and washing with ethanol FIG. 8A,8B: GCMS spectrum for QDs from reference example 1 after treating with PPPA and washing. MS spectrum of peak at retention time of 11.45.

FIG. 9: describes the general scheme of a multi-step method that is established to differentiate between surface and crystal bound ligands, exemplified for dodecaneselenol (DDSe) (scheme1).

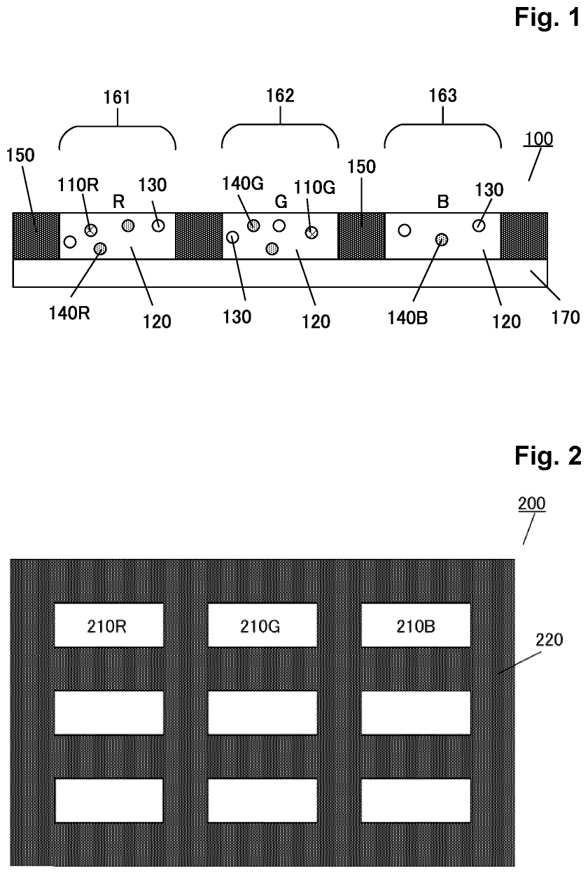

### LIST OF REFERENCE SIGNS IN FIG. 1

100. a color conversion device
110. a light emitting moiety
110R. a light emitting moiety (red)
110G. a light emitting moiety (green)
120. a matrix material
130. a light scattering particle (optional)
140. a coloring agent (optional)
140R. a coloring agent (red) (optional)
140G. a coloring agent (green) (optional)
140B. a coloring agent (blue) (optional)
150. a bank
161. a 1^{st} pixel
162. a 2^{nd} pixel
163. a 3^{rd} pixel
170. a supporting medium (a substrate) (optional)
List of reference signs in FIG. 2
200. a color conversion film
210R. a pixel (red)
210G. a pixel (green)
210B. a pixel (blue)
220. a bank

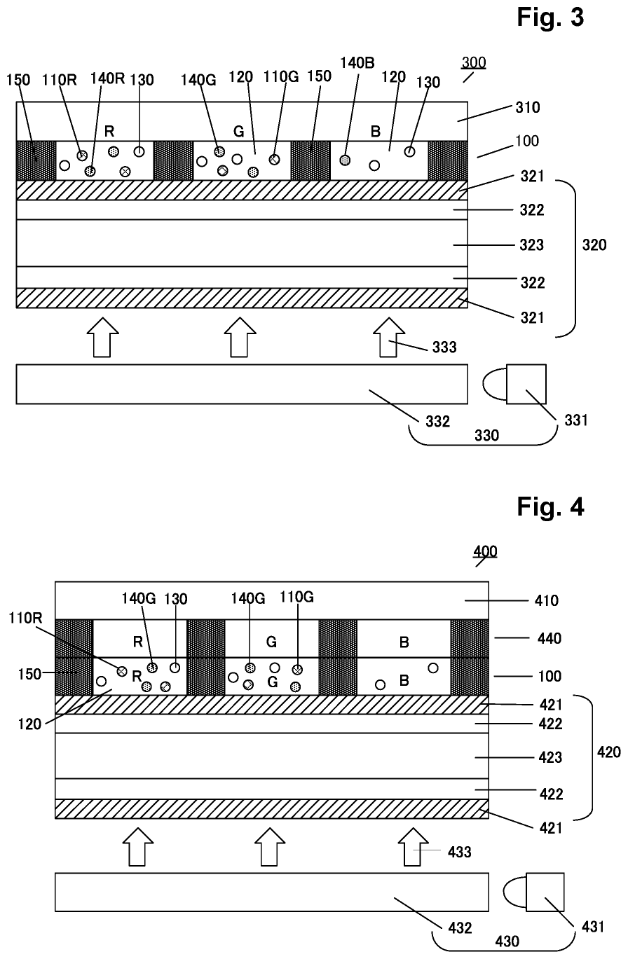

### List of Reference Signs in FIG. 3

300. an optical device
100. a color conversion device
110. a light emitting moiety
110R. a light emitting moiety (red)
110G. a light emitting moiety (green)
120. a matrix material
130. a light scattering particle (optional)
140. a coloring agent (optional)
140R. a coloring agent (red) (optional)
140G. a coloring agent (green) (optional)
140B. a coloring agent (blue) (optional)
150. a bank
320. a light modulator
321. a polarizer
322. an electrode
323. a liquid crystal layer
330. a light source
331. a LED light source
332. a light guiding plate (optional)
333. light emission from the light source (330)

### List of Reference Signs in FIG. 4

400. an optical device
100. a color conversion device
110. a light emitting moiety
110R. a light emitting moiety (red)
110G. a light emitting moiety (green)
120. a matrix material
130. a light scattering particle (optional)
140. a coloring agent (optional)
140R. a coloring agent (red) (optional)
140G. a coloring agent (green) (optional)
140B. a coloring agent (blue) (optional)
150. a bank
420. a light modulator
421. a polarizer
422. an electrode
423. a liquid crystal layer
430. a light source
431. a LED light source
432. a light guiding plate (optional)
440. a color filter
433. light emission from the light source (330)

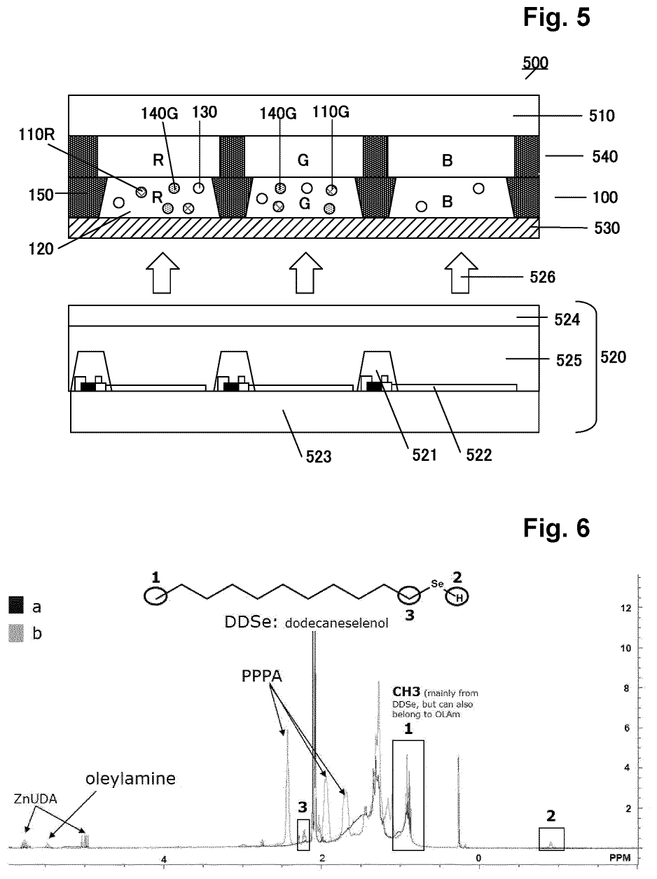

### List of Reference Signs in FIG. 5

500. an optical device
100. a color conversion device
110. a light emitting moiety
11CR. a light emitting moiety (red)
110G. a light emitting moiety (green)
120. a matrix material
130. a light scattering particle (optional)
140. a coloring agent (optional)
140R. a coloring agent (red) (optional)
140G. a coloring agent (green) (optional)
140B. a coloring agent (blue) (optional)
150. a bank
520. a light emitting device (e.g., OLED)
521. a TFT
522. an electrode (anode)
523. a substrate
524. an electrode (cathode)
525. light emitting layer (e.g., OLED layer(s))
526. light emission from a light emitting device (520)
530. an optical layer (e.g., polarizer) (optional)
540. a color filter

### DETAILED DESCRIPTION OF THE INVENTION

According to the present invention, a composition, preferably it is being of a photocurable composition, comprises at least;
i) a light emitting moiety, preferably it is a semiconducting light emitting nanoparticle, comprising an outer layer containing a metal cation and a divalent anion; and
one or more types of organic moieties directly attached to the anion of the outer layer by covalent bond,
ii) at least one reactive monomer or a mixture of two or more reactive monomers, preferably said monomer having one or more of functional groups, more preferably it is a (meth)acrylate monomer,
wherein said divalent anion of the outer layer is selected from Se²⁻, S²⁻, Te²⁻O²⁻ or a combination of any of these, preferably said metal cation of the outer layer is a monovalent, divalent, trivalent or tetravalent cation, more preferably said metal cation is a divalent cation selected from the group consisting of Zn²⁺, Ni²⁺, Co²⁺, Ca²⁺, Sr²⁺, Hg²⁺, Mg²⁺ and Pb²⁺, or a tetravalent cation selected from the group consisting of Ti⁴⁺, Ge⁴⁺, Si⁴⁺, Zr⁴⁺, Hf⁴⁺, and Sn⁴⁺.

### Light Emitting Moiety

According to the present invention, said light emitting moiety may be an organic and/or inorganic light emitting material, preferably it is an organic dye, inorganic phosphor and/or a semiconducting light emitting nanoparticle such as a quantum material. As said organic dye, inorganic phosphor, a semiconducting light emitting nanoparticle, a publicly known one can be used.

Such suitable inorganic light emitting materials described above can be well known phosphors including nanosized phosphors, quantum sized materials like mentioned in the phosphor handbook, 2^{nd} edition (CRC Press, 2006), pp. 155-pp. 338 (W. M. Yen, S. Shionoya and H. Yamamoto), WO2011/147517A, WO2012/034625A, and WO2010/095140A.

As organic dyes, For examples rhodamine, coumarin, pyrromethene, DCM, Fluorescein, umbelliferone, BD Horizon Brilliant™ series can be used.

Preferably said light emitting moiety is an inorganic light emitting material. More preferably it is a semiconducting light emitting nanoparticle. Said semiconducting light emitting nanoparticle is preferably a semiconducting light emitting nanoparticle, comprising, essentially consisting of, or consisting of, a core;
an outer layer covering at least a part of said core, comprising a metal cation and a divalent anion; and
an organic moiety, preferably one or more types of organic moieties directly attached to the anion of the outer layer by covalent bond,
wherein said divalent anion is selected from Se²⁻, S²⁻, Te²⁻O²⁻ or a combination of any of these, preferably said metal cation is a monovalent, divalent cation, trivalent or tetravalent cation, more preferably said metal cation is a divalent cation selected from the group consisting of Zn²⁺, Ni²⁺, Co²⁺, Ca²⁺, Sr²⁺, Hg²⁺, Mg²⁺ and Pb²⁺, or a tetravalent cation selected from the group consisting of Ti⁴⁺, Ge⁴⁺, Si⁴⁺, Zr⁴⁺, Hf⁴⁺, and Sn⁴⁺. Or in some embodiments, metal cation is a transition metal of group 12 or group 14, preferably it is selected from one or more members of the group consisting of Zn²⁺, Hg²⁺ or Pb²⁺.

The nanoparticle comprises at least an outer layer and a core. Said nanoparticle may optionally contain one or more of other layers (shell layers) between the outer layer and the core.

The outer layer covers at least a part of said core. The outer layer may have a direct physical contact with said core if there is no other layers between the outer layer and the core.

The outer layer may cover the core via one or more of additional layers placed between the outer layer and the core.

The term “cover” and the term “covering” do not necessarily mean that there is always a physical contact between the said core and the outer layer. Preferably the core is fully covered by an outer layer and/or one or more of shell layers.

Most preferably, said nanoparticle comprises a core, one or more of shell layers and one outer layer, wherein the outermost shell layer of said one or more of shell layers comprises Zn and S atom.

In a preferred embodiment of the present invention, said outer layer of the light emitting moiety comprises at least two or three different metal cations such as the combination of Cu¹⁺ and In³⁺, Cu¹⁺ and Ga³⁺, Ag¹⁺ and Ga³⁺ or a combination of Cu⁺¹/In⁺³/Zn⁺² from the view point of making an improved covalent bond between the organic moieties and the anions of the outer layer

According to the present invention, the term “nanosized” means the size in between 0.1 nm and 150 nm, preferably 0.5 nm to 100 nm, more preferably 1 nm to 50 nm.

According to the present invention, the term “semiconductor” means a material having electrical conductivity to a degree between that of a conductor (such as copper) and that of an insulator (such as glass) at room temperature, preferably, a semiconductor is a material whose electrical conductivity increases with the temperature.

Therefore, according to the present invention, the term “semiconductor nanoparticle” is taken to mean that a material having electrical conductivity to a degree between that of a conductor (such as copper) and that of an insulator (such as glass) at room temperature, preferably, a semiconductor is a material whose electrical conductivity increases with the temperature and the size is in between 0.1 nm and 999 nm, preferably 0.5 nm to 150 nm, more preferably 1 nm to 50 nm.

According to the present invention, the term “size” means the average diameter of the circle with the area equivalent to the measured TEM projection of the semiconducting nanosized light emitting particles.

In a preferred embodiment of the present invention, the semiconducting light emitting nanoparticle of the present invention is a quantum sized material.

According to the present invention, the term “quantum sized” means the size of the first semiconducting nanoparticle itself without ligands or another surface modification, which can show the quantum confinement effect, like described in, for example, ISBN:978-3-662-44822-9.

Generally, it is said that the quantum sized materials can emit tunable, sharp and vivid colored light due to “quantum confinement” effect.

In some embodiments of the invention, the size of the overall structures of the quantum sized material, is from 1 nm to 50 nm.

In a preferred embodiment of the present invention, the average diameter of the first semiconducting nanoparticle (core) is in the range from 1 to 20 nm, preferably it is in the range from 1.5 to 12 nm.

The average diameter of the semiconducting light emitting nanoparticles (cores) are calculated based on 100 semiconducting light emitting nanoparticles in a TEM image taken by a Tecnai G2 Spirit Twin T-12 Transmission Electron Microscope. The average diameter of the semiconducting light emitting nanoparticles are calculated using Fiji_ImageJ program.

According to the present invention, said semiconducting light emitting nanoparticle may have a core-shell structure. In case said semiconducting light emitting nanoparticle does not have any shell layer, then the term “core” means semiconducting light emitting nanoparticle itself.

In some embodiments of the present invention, the core comprises at least one element of group 12 or group 13 elements of the periodic table and one element of group 15 or 16 elements of the periodic table.

In a preferred embodiment of the present invention, the 1^{st} semiconducting material (hereafter “core” of the semiconducting light emitting nanoparticle”) comprises at least one element of the group 13 of the periodic table, and one element of the group 15 of the periodic table, preferably the element of the group 13 is In, and the element of the group 15 is P.

In a preferred embodiment of the present invention, the first core can further comprise additional element selected from one or more member of the group consisting of Ga, Zn, S, and Se.

In some embodiments the core is a metal oxide comprising for example ZnO, FeO, Fe₂O₃, ZrO₂, CuO, SnO Cu₂O, TiO₂, WO₃, HfO₂, In₂O₃, MgO, Al₂O₃ and any combination of these.

In some embodiments the core comprises a metal, for example Au, Ag, W, Pd, Pt, Cu, In, Ti, Zn, Pb, Al, Cd, Zn and a combination of any of these.

In a more preferable embodiment, the core is selected from the group consisting of InP, InPZn, InPZnS, InPZnSe, InPZnSeS, InPZnGa, InPGaS, InPGaSe, InPGaSeS, InPZnGaSeS and InPGa.

According to the present invention, a type of shape of the core of the semiconducting light emitting nanoparticle, and shape of the semiconducting light emitting nanoparticle to be synthesized are not particularly limited.

For examples, spherical shaped, elongated shaped, star shaped, polyhedron shaped, pyramidal shaped, tetrapod shaped, tetrahedron shaped, platelet shaped, cone shaped, and irregular shaped core and—or a semiconducting light emitting nanoparticle can be synthesized.

### Shell Layer

According to the present invention, in a preferable embodiment, the core is at least partially embedded in the first shell layer, more preferably said core is fully embedded into one or more shell layers. In a preferred embodiment of the present invention, said shell layer(s) are placed in between the core and the outer layer. In other words, the semiconducting light emitting nanoparticle of the present invention optionally may comprise, essentially consisting of, or consisting of a core, one or more shell layers covering said core, an outer layer covering said shell layers in this sequence.

### First Shell Layer

In some embodiments of the present invention, said shell layer comprises at least one metal cation and at least one divalent anion as described in the section of outer layer and/or at least a 1^{st} element of group 12 of the periodic table and a Se atom or a S atom, preferably, the 1^{st} element is Zn.

For example, said first shell layer is selected from the group consisting of Cs₂S, Cs₂Se, Cs₂Te, Cs₂₀, Ag₂S, Ag₂Se, Ag₂Te, Ag₂O, Au₂S, Au₂Se, Au₂Te, Au₂O, Cu₂S, Cu₂Se, Cu₂Te, Cu₂O, ZnS, ZnSe, ZnTe, ZnO, CdS, CdSe, CdTe, CdO, CaS, CaSe, CaTe, CaO, NiS, NiSe, NiTe, NiO, MgS, MgSe, MgTe, MgO, HgS, HgSe, HgTe, HgO, PbS, PbSe, PbTe, PbO, CuS, CuSe, CuTe, CuO, CoS, CoSe, CoTe, CoO, SrO, SrS, SrSe, CoTe, SrO, FeS, FeSe, FeO, FeTe, In₂S₃, In₂Se₃, In₂Te₃, In₂₀₃, Ga₂S₃, Ga₂Se₃, Ga₂Te₃, Ga₂₀₃, Bi₂S₃, Bi₂Se₃, Bi₂Te₃, Bi₂₀₃, Fe₂S₃, Fe₂Se₃, Fe₂Te₃, Fe₂O₃, TiS₂, TiSe₂, TiTe₂, TiO₂, SiS₂, SiSe₂, SiTe₂, SiO₂, ZrS₂, ZrSe₂, ZrTe₂, ZrO₂, HfS₂, HfSe₂, HfTe₂, HfO₂, SnS₂, SnSe₂, SnTe₂, SnO₂, GeS₂, GeSe₂, GeTe₂, GeO, CuInZnS, CuInS₂, CuInZnSe, CuInSe₂, AgInZnS, AgInZnSe, CuGaZnS, CuGaZnSe, CuFeS₂, CuFeSe₂ and a combination of any of these.

Preferably it is selected from the group consisting of ZnS, ZnSe, ZnTe, ZnO, CdS, CdSe, CdTe, CdO, CaS, CaSe, CaTe, CaO, NiS, NiSe, NiTe, NiO, MgS, MgSe, MgTe, MgO, HgS, HgSe, HgTe, HgO, PbS, PbSe, PbTe, PbO, CuS, CuSe, CuTe, CuO, CoS, CoSe, CoTe, CoO, SrO, SrS, SrSe, CoTe, SrO, FeS, FeSe, FeO, FeTe and a combination of any of these materials

More preferably: ZnS, ZnSe, ZnTe, ZnO or a combination of any of these materials

In some embodiments of the present invention, at least one (first) the shell layer comprises or a consisting of a 1^{st} element of group 12 of the periodic table and a 2^{nd} element of group 16 of the periodic table, preferably, the 1^{st} element is Zn, and the 2^{nd} element is S, Se, or Te; preferably a first shell layer covering directly onto said core comprises or a consisting of a 1^{st} element of group 12 of the periodic table and a 2^{nd} element of group 16 of the periodic table, preferably, the 1^{st} element is Zn, and the 2^{nd} element is S, Se, or Te.

In a preferred embodiment of the present invention, at least one shell layer (a first shell layer) is represented by following formula (XI), preferably the shell layer directly covering the core is represented by the chemical formula (XI);

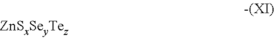

wherein 0≤x≤1, 0≤y≤1, 0≤z≤1, and x+y+z=1, preferably 0≤x≤1, 0≤y≤1, z=0, and x+y=1, preferably, the shell layer is ZnSe, ZnSxSey, ZnS, ZnSeyTez or ZnSxTez.

In some embodiments of the present invention, said shell layer is an alloyed shell layer or a graded shell layer, preferably said graded shell layer is ZnSxSey, ZnSeyTez, or ZnSxTez, more preferably it is ZnSxSey.

In some embodiments of the present invention, the semiconducting light emitting nanoparticle further comprises 2^{nd} shell layer onto said shell layer, preferably the 2^{nd} shell layer comprises or a consisting of a 3^{rd} element of group 12 of the periodic table and a 4^{th} element of group 16 of the periodic table, more preferably the 3^{rd} element is Zn, and the 4^{th} element is S, Se, or Te with the proviso that the 4^{th} element and the 2^{nd} element are not same.

In some embodiments of the present invention, optionally, the first semiconducting nanoparticle as a core and a first shell layer can be at least partially embedded in the 2^{nd} shell, preferably said first semiconducting nanoparticle is fully embedded into the shell layer.

For example, said second shell layer is selected from the group consisting of Cs₂S, Cs₂Se, Cs₂Te, Cs₂₀, Ag₂S, Ag₂Se, Ag₂Te, Ag₂O, Au₂S, Au₂Se, Au₂Te, Au₂O, Cu₂S, Cu₂Se, Cu₂Te, Cu₂O, ZnS, ZnSe, ZnTe, ZnO, CdS, CdSe, CdTe, CdO, CaS, CaSe, CaTe, CaO, NiS, NiSe, NiTe, NiO, MgS, MgSe, MgTe, MgO, HgS, HgSe, HgTe, HgO, PbS, PbSe, PbTe, PbO, CuS, CuSe, CuTe, CuO, CoS, CoSe, CoTe, CoO, SrO, SrS, SrSe, CoTe, SrO, FeS, FeSe, FeO, FeTe, In₂S₃, In₂Se₃, In₂Te₃, In₂₀₃, Ga₂S₃, Ga₂Se₃, Ga₂Te₃, Ga₂₀₃, Bi₂S₃, Bi₂Se₃, Bi₂Te₃, Bi₂₀₃, Fe₂S₃, Fe₂Se₃, Fe₂Te₃, Fe₂O₃, TiS₂, TiSe₂, TiTe₂, TiO₂, SiS₂, SiSe₂, SiTe₂, SiO₂, ZrS₂, ZrSe₂, ZrTe₂, ZrO₂, HfS₂, HfSe₂, HfTe₂, HfO₂, SnS₂, SnSe₂, SnTe₂, SnO₂, GeS₂, GeSe₂, GeTe₂, GeO, CuInZnS, CuInS₂, CuInZnSe, CuInSe₂, AgInZnS, AgInZnSe, CuGaZnS, CuGaZnSe, CuFeS₂, CuFeSe₂ and a combination of any of these.

Preferably it is selected from the group consisting of ZnS, ZnSe, ZnTe, ZnO, CdS, CdSe, CdTe, CdO, CaS, CaSe, CaTe, CaO, NiS, NiSe, NiTe, NiO, MgS, MgSe, MgTe, MgO, HgS, HgSe, HgTe, HgO, PbS, PbSe, PbTe, PbO, CuS, CuSe, CuTe, CuO, CoS, CoSe, CoTe, CoO, SrO, SrS, SrSe, CoTe, SrO, FeS, FeSe, FeO, FeTe and a combination of any of these materials More preferably: ZnS, ZnSe, ZnTe, ZnO or a combination of any of these materials.

In some embodiments of the present invention, said 2^{nd} shell layer comprises at least a 1^{st} element of group 12 of the periodic table and a 2nd element of group 16 of the periodic table, preferably, the 1^{st} element is Zn, and the 2^{nd} element is S, Se, O, or Te.

In a preferred embodiment of the present invention, the 2^{nd} shell layer is represented by following formula (XI′),

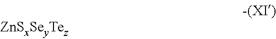

wherein 0≤x≤1, 0≤y≤1, 0≤z≤1, and x+y+z=1, preferably, the shell layer is ZnSe, ZnSxSey, ZnSeyTez, or ZnSxTez with the proviso that the shell layer and the 2^{nd} shell layer is not the same.

In some embodiments of the present invention, said 2^{nd} shell layer can be an alloyed shell layer.

In some embodiments of the present invention, the semiconducting light emitting nanoparticle can further comprise one or more additional shell layers onto the 2^{nd} shell layer as a multishell.

According to the present invention, the term “multishell” stands for the stacked shell layers consisting of three or more shell layers.

For examples, as a shell layer, CdS, CdZnS, CdS/ZnS, CdS, ZnS, ZnS/ZnSe, ZnSe/ZnS or combination of any of these can be used. Preferably, ZnS, ZnSe or ZnSe/ZnS.

For examples, as a semiconducting light emitting materials having core/shell structure, CdSe/CdS, CdSeS/CdZnS, CdSeS/CdS/ZnS, ZnSe/CdS, CdSe/ZnS, InP/ZnS, InP/ZnSe, InP/ZnSe/ZnS, InZnP/ZnS, InZnP/ZnSe, InZnP/ZnSe/ZnS, InGaP/ZnS, InGaP/ZnSe, InGaP/ZnSe/ZnS, InZnPS/ZnS, InZnPS/ZnSe, InZnPS/ZnSe/ZnS, ZnSe/CdS, ZnSe/ZnS or combination of any of these, can be used. Preferably, InP/ZnS, InP/ZnSe, InP/ZnSe/ZnS, InZnP/ZnS, InZnP/ZnSe, InZnP/ZnSe/ZnS, InGaP/ZnS, InGaP/ZnSe, InGaP/ZnSe/ZnS.

Such semiconducting light emitting nanoparticles are publicly available (for example from Sigma Aldrich) and/or can be synthesized with the method described for example in U.S. Pat. Nos. 7,588,828 B, 8,679,543 B and Chem. Mater. 2015, 27, pp 4893-4898.

### Organic Moiety

In a preferred embodiment of the present invention, the organic moiety is represented by following chemical formula (I);

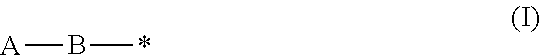

wherein
A is an organic group, preferably said organic group is hydrocarbyl (alkyl, aryl, aralkyl and alkylaryl), heteroaromatic group, including aryl, alkaryl, alkyl or aralkyl, alkylamine, fluoroaryl, fluoroalkaryl, fluoroalkyl, fluoroaralkyl, heteroaromatic group, including fluoroaryl, fluoroalkaryl, fluoroalkyl or fluoroaralkyl;
B is a connecting unit, preferably B is **-(U)ₒ-(Y)ₘ—(CR^{IIa}R^{IIb})ₙ wherein represents the connecting point to “A;” and
“*” represents the connecting point to the anion in the outer layer.

More preferably, the organic moiety is represented by following chemical formula (II), (III) or (III′);

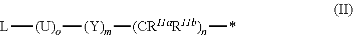

wherein
L is an organic group, preferably said organic group is hydrocarbyl (alkyl, aryl, aralkyl and alkylaryl), heteroaromatic group, including aryl, alkaryl, alkyl or aralkyl, alkylamine, fluoroaryl, fluoroalkaryl, fluoroalkyl, fluoroaralkyl, heteroaromatic group, including fluoroaryl, fluoroalkaryl, fluoroalkyl or fluoroaralkyl;
U is O, CH₂ or C═O;
Y is O, CH₂ or C═O;
R^{IIa} and R^{IIb} are, each independently each other, at each occurrence, selected from hydrogen atom, a hydroxy group, a straight alkyl group having 1 to 10 carbon atoms, a branched alkyl group having 3 to 10 carbon atoms; preferably a hydrogen atom, a hydroxy group, a straight alkyl group having 1 to 5 carbon atoms, a branched alkyl group having 3 to 5 carbon atoms; preferably R^{IIa} and R^{IIb} are hydrogen atom;
n is an integer 1 or more;
m is 0 or an integer 1 or more, preferably m is 1;
o is 0 or an integer 1 or more, preferably o is 1;
“*” represents the connecting point to the anion in the outer layer;

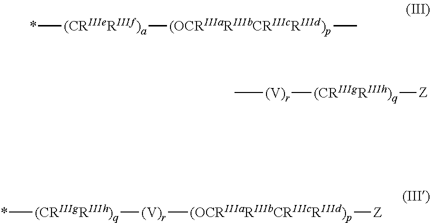

wherein
R^{IIIa}, R^{IIIb}, R^{IIIc}, R^{IIId}, R^{IIIe}, R^{IIIf}, R^{IIIg} and R^{IIIh} are, each independently each other, at each occurrence, selected from hydrogen atom, a hydroxy group, a straight alkyl group having 1 to 10 carbon atoms, a branched alkyl group having 3 to 10 carbon atoms; preferably a hydrogen atom, a hydroxy group, a straight alkyl group having 1 to 5 carbon atoms, a branched alkyl group having 3 to 5 carbon atoms; preferably R^{IIIg} and R^{IIIh} are hydrogen atom, preferably R^{IIIe} and R^{IIIf} are hydrogen atom; V is O, CH₂ or C═O;
is a hydrogen atom or an organic group, preferably Z is a hydrogen atom, a straight alkyl group having 1 to 25 carbon atoms, a branched alkyl group having 3 to 25 carbon atoms, —COOH, —SH, or —NH₂, alkylamine, fluoroaryl, fluoroalkaryl, fluoroalkyl, fluoroaralkyl, heteroaromatic group, including fluoroaryl, fluoroalkaryl, fluoroalkyl or fluoroaralkyl, preferably Z is a hydrogen atom, a straight alkyl group having 1 to 25 carbon atoms, a branched alkyl group having 3 to 25 carbon atoms, more preferably it is a hydrogen atom, a straight alkyl group having 1-15 carbon atoms, a branched alkyl group having 3-15 carbon atoms, even more preferably it is a hydrogen atom, or a straight alkyl group having 1-10 carbon atoms;
a is 0 or an integer 1 or more, preferably 0≤a≤25, more preferably 0≤a≤15, even more preferably 1≤a≤10;
p is 0 or an integer 1 or more, preferably 0≤p≤45, more preferably 0≤p≤25, even more preferably 1≤p≤20, furthermore preferably 4≤p≤18;
q is 0 or an integer 1 or more, preferably 0≤q≤25, more preferably 0≤q≤15, even more preferably 0≤q≤10, furthermore preferably it is 1≤q≤5;
r is 0 or an integer 1;
“*” represents the connecting point to the anion in the outer layer.

Even more preferably, the organic moiety is represented by following chemical formula (IV):

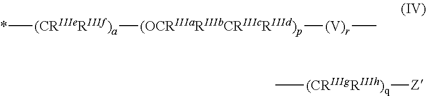

wherein
R^{IIIa}, R^{IIIb}, R^{IIIc}, R^{IIId}, R^{IIIe}, R^{IIIf}, R^{IIIg} and R^{IIIh} are, each independently each other, at each occurrence, selected from hydrogen atom, a hydroxy group, a straight alkyl group having 1 to 10 carbon atoms, a branched alkyl group having 3 to 10 carbon atoms; preferably a hydrogen atom, a hydroxy group, a straight alkyl group having 1 to 5 carbon atoms, a branched alkyl group having 3 to 5 carbon atoms; preferably R^{IIIg} and R^{IIIh} are hydrogen atom, preferably R^{IIIe} and R^{IIIf} are hydrogen atom;
a is 0 or an integer 1 or more, preferably 0≤a≤25, more preferably 0≤a≤15, even more preferably 1≤a≤10;
p is 0 or an integer 1 or more, preferably 0≤p≤45, more preferably 0≤p≤25, even more preferably 1≤p≤20, furthermore preferably 4≤p≤18;
q is 0 or an integer 1 or more, preferably 0≤q≤25, more preferably 0≤q≤15, even more preferably 0≤q≤10, furthermore preferably it is 1;
V is O, CH₂ or C═O;
Z′ is a hydrogen atom a straight alkyl group having 1 to 25 carbon atoms, a branched alkyl group having 3 to 25 carbon atoms, alkylamine, fluoroaryl, fluoroalkaryl, fluoroalkyl, fluoroaralkyl, heteroaromatic group, including fluoroaryl, fluoroalkaryl, fluoroalkyl or fluoroaralkyl, preferably Z′ is a straight alkyl group having 1 to 25 carbon atoms, a branched alkyl group having 3 to 25 carbon atoms or a hydrogen atom, more preferably it is a straight alkyl group having 1-15 carbon atoms, a branched alkyl group having 3-15 carbon atoms or a hydrogen atom, even more preferably it is a hydrogen atom;
r is 0 or an integer 1;
“*” represents the connecting point to the anion in the outer layer, preferably it is connected to S or Se atom in the outer layer.

In some of the preferred embodiments the organic moiety is CH₃—(CH₂)_{7<n<18}—* and connecting to the S or Se atom in the outer layer.

In a preferred embodiment of the present invention, the organic moiety selected from chemical formula (I), (II), (III), (III′) or (IV) is covalently bound to the anion in an inorganic lattice of the outer layer, preferably it is not removed by a ligand exchange.

Crystal bound ligands (covalently bound ligands) can be characterized as described in reference example 7.

For examples, the organic moiety can be described as follows preferably.

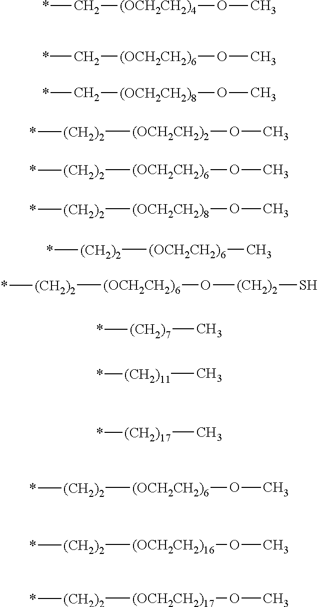

“*” represents the connecting point to S atom or Se atom in the outer layer,
or

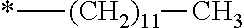

“*” represents the connecting point to Se atom or S atom in the outer layer.

Other thiolated ligand materials like polypropyleneglycol and polypropyleneglycol monomethyl ether, thiolated ligand materials described in U.S. Ser. No. 11/021,651 B2, formula (I), formula (II) of column 17-18, line 28 of column 25 to line 16 of column 26, M1000-SH of Example 1 can also be used as a source of organic moiety and the resulting covalently bonded organic moiety is included in this patent application.

It is believed that the organic moiety prevents aggregation of nanoparticles or nanosized material, the organic moiety allows to disperse the nanoparticles in the organic medium and/or in aqueous medium.

Especially, it is believed that the organic moiety directly attached to the anion of the outer layer of the light emitting moiety by covalent bond can realize one or more of the technical effects of the present invention when it is mixed with the reactive monomer or a mixture of two or more reactive monomers of the present invention. Preferably said reactive monomer or two or more reactive monomers of the monomer mixture is a (meth)acrylate monomer(s). More preferably it is a specific (meth)acrylate monomer as defined in the section of reactive monomer below. It is believed that such specific combination of a light emitting moiety having covalently bonded organic moieties attached directly onto an outer layer of the light emitting moiety and specific (meth)acrylate monomer(s) can surprisingly improve thermal stability of an obtained layer (film), thermal stability of a light emitting moiety in a layer (film), dispersibility of a light emitting moiety in a composition, dispersibility of a light emitting moiety in an obtained layer enabling a phase separation of light emitting moiety and matrix material after curing realizing an improved haze value of the cured film (cured composition), long term Quantum Yield (QY) stability of a light emitting moiety in the composition in a longer term storage with or without light irradiation, long term External Quantum Efficiency (EQE) stability of a light emitting moiety in the composition in a longer term storage with or without light irradiation, long term Quantum Yield (QY) stability of a light emitting moiety in the obtained layer (film) in a longer term storage with or without light irradiation, long term External Quantum Efficiency (EQE) stability of a light emitting moiety in the obtained layer (film) in a longer term storage with or without light irradiation, good compatibility of light emitting moiety with a matrix material in a composition and/or an obtained layer (film), and/or realizing easy handling of a composition containing a light emitting moiety and a matrix material.

In some embodiments the organic moiety may comprise a zwitterionic group.

### Outer Layer

According to the present invention, the semiconducting nanoparticle comprises an outer layer covering at least a part of said core, comprising at least one metal cation and at least one divalent anion, wherein said divalent anion is selected from Se²⁻, S²⁻, Te²⁻O²⁻ or a combination of any of these, preferably said metal cation is a monovalent, divalent cation, trivalent or tetravalent cation, more preferably said metal cation is a divalent cation selected from the group consisting of Zn²⁺, Ni²⁺, Co²⁺, Ca²⁺, Sr²⁺, Fe²⁺, Hg²⁺, Mg²⁺ and Pb²⁺, or a tetravalent cation selected from the group consisting of Ti⁴⁺, Ge⁴⁺, Si⁴⁺, Zr⁴⁺, Hf⁴⁺, and Sn⁴⁺, In some embodiments cation is monovalent cation selected from the group consisting of Cs⁺, Ag⁺, Au⁺, Cu⁺¹ or a divalent cation selected from the group consisting of Zn²⁺, Fe⁺², Ni²⁺, Co²⁺, Ca²⁺, Sr²⁺, Hg²⁺, Mg²⁺ and Pb²⁺Cu⁺² or a trivalent cation selected from the group Fe⁺³, In⁺³, Bi⁺³, Ga⁺³ a tetravalent cation selected from the group consisting of Ti⁴⁺, Ge⁴⁺, Si⁴⁺, Zr⁴⁺Hf⁴⁺, and Sn⁴⁺, Si⁺⁴.

In some embodiments of the present invention, said outer layer comprises at least two or three different metal cations such as the combination of Cu¹⁺ and In³⁺, Cu¹⁺ and Ga³⁺, Ag¹⁺ and Ga³⁺ or a combination of Cu⁺¹/In⁺³/Zn⁺² or a combination of Cu⁺¹/Ga⁺³/Zn⁺² or a combination of Cu⁺¹/In⁺³/Ga⁺³/Zn⁺² or a combination of Cu⁺¹/In⁺³/Ga⁺³ In a preferred embodiment, the metal cation is a divalent cation selected from the group consisting of Fe⁺² Zn²⁺, Ni²⁺, Co²⁺, Ca²⁺, Sr²⁺, Hg²⁺, Mg²⁺ and Pb²⁺, Cu⁺².

In a preferred embodiment of the present invention, said outer layer comprising, essentially consisting of, or consisting of a material represented by following chemical formula (VI),

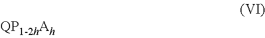

wherein Q is a divalent anion selected from one or more members of the group consisting of Se²⁻, S²⁻, Te²⁻ and O²⁻;
P is a divalent metal cation, preferably P is a divalent cation selected from one or more member of the group consisting of Zn²⁺, Ni²⁺, Co²⁺, Ca²⁺, Sr²⁺, Hg²⁺, Mg²⁺ and Pb²⁺;
A is a tetravalent cation, preferably A is selected from one or more members of the group consisting of Ti⁴⁺, Ge⁴⁺, Si⁴⁺, and Sn⁴⁺; and 0≤h≤0.5.

For examples, ZnS, ZnSe, ZnSeS, ZnTe, ZnO, ZnNiS, ZnNiSe, ZnGeS, ZnGeO, ZnCaS, NiSe, TiGeSeS, ZnTiS, CuInZnS, CuInZnSe, AgInZnS, and/or AgInZnSe can be used.

According to the present invention, preferably said outer layer is a monolayer.

More preferably, it is a last monolayer of the semiconducting nanoparticle covering the core. In case there is one or more of shell layers covering the core, then the outer layer is covering the shell layers.

In some embodiments of the present invention, the concentration of Se in the shell layer varies from a high concentration of the first semiconducting nanoparticle side in the shell layer to a low concentration of the opposite side in the shell layer, more preferably, the concentration of S in the shell layer varies from a low concentration of first semiconducting nanoparticle side of the shell layer to a higher concentration to the opposite side of the shell layer, the concentration of Te in the shell layer varies from a high concentration of first semiconducting nanoparticle side of the shell layer to a lower concentration to the opposite side of the shell layer.

In some embodiments of the present invention, the surface of the light emitting moiety, namely a semiconducting light emitting nanoparticle can be over coated with one or more kinds of surface ligands in addition to the organic moiety of the present invention.

Without wishing to be bound by theory it is believed that such surface ligands may lead to disperse the nanosized fluorescent material in a solvent more easily.

The surface ligands in common use include phosphines and phosphine oxides such as Trioctylphosphine oxide (TOPO), Trioctylphosphine (TOP), and Tributylphosphine (TBP); phosphonic acids such as Dodecylphosphonic acid (DDPA), Tridecylphosphonic acid (TDPA), amines such as Oleylamine, Dodecyl amine (DDA), Tetradecyl amine (TDA), Hexadecyl amine (I), and Octadecyl amine (ODA), Oleylamine (OLA), 1-Octadecene (ODE); thiols, when organic moiety of thiol may include linear or branched alkyl chain which can be saturated or include one or more unsaturated carbon bonds and/or aromatic rings, such as octadecane thiol, hexadecane thiol, dodecane thiol, hexane thiol and polyethylene glycol thiols; selenols, when organic moiety of selenol may include linear or branched alkyl chain which can be saturated or include one or more unsaturated carbon bonds and/or aromatic rings; mercapto carboxylic acids such as mercapto propionic acid and mercaptoundecanoicacid; carboxylic acids such as oleic acid, stearic acid, myristic acid, isostearic acid; acetic acid and a combination of any of these. Furthermore, the ligands can include Zn-oleate, Zn-acetate, Zn-myristate, Zn-Stearate, Zn-laurate and other Zn-carboxylates, Zn-isostearate, sulfonic acids, halides, carbamates.

Examples of surface ligands have been described in, for example, the laid-open international patent application No. WO 2012/059931A.

### Measurement of Quantum Yield

According to the present invention the Quantum Yield of the quantum dots (QY) is measured using Hamamatsu absolute quantum yield spectrometer (model: Quantaurus C11347).

Preferably, the nanoparticle emits light having the peak maximum light emission wavelength in the range from 350 nm 3500 nm, preferably from 350 nm to 2000 nm, more preferably from 400 nm to 800 nm, even more preferably from 430 nm to 700 nm.
Analysis of nanoparticles, preferably quantum dots (QDs) by GCMS According to the present invention the gas chromatography mass spectrometry (GCMS) is performed using Agilent Technologies 7890B GC system equipped with autosampler and Agilent DB-5 column and MS instrument Agilent Technologies 5977B MSD. The analytes are separated using the following injection method: initial temperature 100° C., hold 0 min at 100° C.; heat to 340° C. at the rate of 8° C./min, hold 15 min at 340° C.

Samples for GCMS are prepared as follows:
3.1 Weight the starting material.
3.2 Calculate the organic content based on TGA measurement.
3.3 For each 30 mg of organic component add 10 ml methanol and 5 ml of concentrated hydrochloric acid (caution! exothermic reaction) to dissolve the nanoparticles, preferably quantum dots (QDs). If the color still persists, use sonication and Vortex.
3.4 Place magnetic stirrer and heat the solution at 60° C. for 20 min (do not heat in closed flask! Make sure that the stopper is partially open)
3.5 Transfer the solution to separating funnel. Add toluene (10 ml for 30 mg of organic material).
3.6 Extract the water phase and remove the lower aqueous phase.
3.7 Add 20 ml distilled water to funnel and extract the toluene phase again.
3.8 Repeat the extraction of the toluene phase with water at least 3 times or until the water phase have the pH of distilled water (~5).
3.9 Collect the upper phase to a flask containing MgSO4 for at least 30 min. Filter the MgSO4 solids.
3.10 Transfer the toluene mixture to the GC vials for injection.

### Reactive Monomer

It is believed that the lower viscosity is important to make a low viscosity composition suitable for inkjet printing. Therefore, a (meth)acrylate monomer having the viscosity value within the above-mentioned parameter ranges are especially suitable to make a composition for inkjet printing. By using these (meth)acrylate monomer in a composition, when it is mixed with another material such as semiconducting light emitting nanoparticles with high loading, the composition can still keep lower viscosity within the range suitable for inkjet printing.

Further, it is believed that a combination of the reactive monomer or a mixture of two or more reactive monomers, preferably a (meth)acrylate monomer or a mixture of two or more (meth)acrylate monomers of the present invention, and the light emitting moiety comprising an outer layer containing a metal cation and a divalent anion, and one or more types of organic moieties directly attached to the anion of the outer layer by covalent bond; may specifically improve optical performance of the light emitting moiety in an obtained layer (film).

It is also believed that said combination may also lead improve thermal stability of an obtained layer (film), thermal stability of a light emitting moiety in a layer (film), dispersibility of a light emitting moiety in a composition, dispersibility of a light emitting moiety in an obtained layer enabling a phase separation of light emitting moiety and matrix material after curing realizing an improved haze value of the cured film (cured composition), long term Quantum Yield (QY) stability of a light emitting moiety in the composition in a longer term storage with or without light irradiation, long term External Quantum Efficiency (EQE) stability of a light emitting moiety in the composition in a longer term storage with or without light irradiation, long term Quantum Yield (QY) stability of a light emitting moiety in the obtained layer (film) in a longer term storage with or without light irradiation, long term External Quantum Efficiency (EQE) stability of a light emitting moiety in the obtained layer (film) in a longer term storage with or without light irradiation, good compatibility of light emitting moiety with a matrix material in a composition and/or an obtained layer (film), and/or realizing easy handling of a composition containing a light emitting moiety and a matrix material.

In a preferred embodiment of the present invention, the boiling point (B.P.) of said reactive monomer is 95° C. or more, preferably it is in the range from 95° C. to 350° C., for large area uniform inkjet printing.

It is believed that said high boiling point is also important to make a composition having a lower vapor pressure preferably less than 0.001 mmHg for large area uniform printing, it is preferable to use a reactive monomer, preferably a (meth)acrylate monomer, more preferably a (meth)acrylate monomer of formula (I), (II) and/or (III) having the viscosity value of 25 cP or less at 25° C. and the boiling point at least 95° C. or more, preferably it is in the range from 95° C. to 350° C., to make a composition suitable for large area uniform inkjet printing even if it is mixed with high loading of another materials such as high loading of semiconducting light emitting nanoparticles.

Here, the term “(meth)acrylate” is a general term for an acrylate and a methacrylate. Therefore, according to the present invention, the term “(meth)acrylate monomer” means a methacrylate monomer and/or an acrylate monomer.

According to the present invention, said B.P can be estimate by the known method such as like described in Science of Petroleum, Vol. 11. p.1281 (1398).

According to the present invention, any types of publicly available acrylates and/or methacrylates represented by chemical formula (I) or (II) can be used preferably.

Especially for the first aspect, any types of publicly available acrylates and/or methacrylates having the viscosity value of 25 cP or less at 25° C. represented by chemical formula (I), (II) and/or (III) can be used.

Thus, according to the present invention, the reactive monomer of the composition is preferably a (meth)acrylate monomer selected from a mono-(meth)acrylate monomer, a di-(meth)acrylate monomer and/or a tri-(meth)acrylate monomer.

Preferably said reactive monomers of the monomer mixture is each independently selected from a mono-(meth)acrylate monomer, a di-(meth)acrylate monomer and/or a tri-(meth)acrylate monomer.

Preferably, said di-(meth)acrylate monomer is represented by following chemical formula (I^{b}), said mono-acrylate monomer is represented by following chemical formula (II^{b}) and/or said tri-(meth)acrylate monomer is represented by following chemical formula (III^{b})

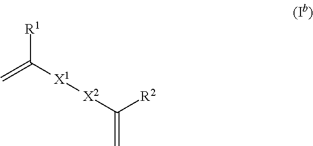

wherein
X¹ is a non-substituted or substituted ester group, alkyl group or aryl group, where one or more non-adjacent CH₂ groups of ester, alkyl or aryl group may be replaced by oxygen atom, C═O, C═S, C═Se, C═NH, SiH₂, SO, SO₂, OS, or CONH and where one or more H atoms may be replaced by D, F, Cl, Br, I, CN or NO₂; preferably said ester group is represented by following formula (I^{bs1});

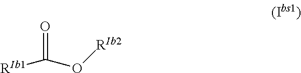

wherein R^{Ib1} is a single bond, a non-substituted or substituted alkylene chain having carbon atoms 1 to 5;
R^{Ib2} is a single bond, a non-substituted or substituted straight alkylene chain having carbon atoms 1 to 5, a non-substituted or substituted branched alkylene chain having carbon atoms 3 to 7, where one or more non-adjacent CH₂ groups may be replaced by oxygen atom, C═O, C═S, C═Se, C═NH, SiH₂, SO, SO₂, OS, or CONH and where one or more H atoms may be replaced by D, F, Cl, Br, I, CN or NO₂; preferably R^{Ib2} is a non-substituted or substituted branched alkylene chain having carbon atoms 3 to 7, where at least one of non-adjacent CH₂ groups may be replaced by oxygen atom, C═O, C═S, C═Se, C═NH, SiH₂, SO, SO₂, OS, or CONH and where one or more H atoms may be replaced by D, F, Cl, Br, I, CN or NO₂;
X² is a non-substituted or substituted non-substituted or substituted ester group, alkyl group or aryl group, where one or more non-adjacent CH₂ groups of ester, alkyl or aryl group may be replaced by oxygen atom, C═O, C═S, C═Se, C═NH, SiH₂, SO, SO₂, OS, or CONH and where one or more H atoms may be replaced by D, F, Cl, Br, I, CN or NO₂; preferably said ester group is represented by following formula (I^{bs2});

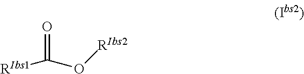

wherein R^{Ibs1} is a single bond, a non-substituted or substituted alkylene chain having carbon atoms 1 to 5;
R^{Ibs2} is a single bond, a non-substituted or substituted straight alkylene chain having carbon atoms 1 to 5, a non-substituted or substituted branched alkylene chain having carbon atoms 3 to 7, where one or more non-adjacent CH₂ groups may be replaced by oxygen atom, C═O, C═S, C═Se, C═NH, SiH₂, SO, SO₂, OS, or CONH and where one or more H atoms may be replaced by D, F, Cl, Br, I, CN or NO₂; preferably R^{Ib2} is a non-substituted or substituted branched alkylene chain having carbon atoms 3 to 7, where at least one of non-adjacent CH₂ groups may be replaced by oxygen atom, C═O, C═S, C═Se, C═NH, SiH₂, SO, SO₂, OS, or CONH and where one or more H atoms may be replaced by D, F, Cl, Br, I, CN or NO₂;
R¹ is a hydrogen atom, halogen atom of Cl, Br, or F, methyl group, alkyl group, aryl group, where one or more non-adjacent CH₂ groups of alkyl or aryl group may be replaced by oxygen atom, C═O, C═S, C═Se, C═NH, SiH₂, SO, SO₂, OS, or CONH and where one or more H atoms may be replaced by D, F, Cl, Br, I, CN or NO₂; or X¹ is an ester group; preferably said ester group is a carboxylic acid group;
R² is a hydrogen atom, halogen atom of Cl, Br, or F, methyl group, alkyl group, aryl group, where one or more non-adjacent CH₂ groups of alkyl or aryl group may be replaced by oxygen atom, C═O, C═S, C═Se, C═NH, SiH₂, SO, SO₂, OS, or CONH and where one or more H atoms may be replaced by D, F, Cl, Br, I, CN or NO₂; or X¹ is an ester group; preferably said ester group is a carboxylic acid group;
preferably the symbol X¹ is ester group of formula (I^{bs1}) or

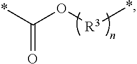

where “*” on the left side of the formula represents the connecting point to the carbon atom of the end group C═CR¹ of the formula (I) and “*” on the right side represents the connecting point to symbol X² of the formula (I);
n is 0 or 1;
preferably the symbol X² is ester group of formula (I^{bs2}) or

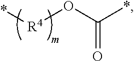

where “*” on the left side of the formula represents the connecting point to symbol X1 of the formula (I) and “*” on the right side represents the connecting point to the end group C═CR² of the formula (I);
m is 0 or 1;
preferably at least m or n is 1;
R³ is a straight alkylene chain or alkoxylene chain having 1 to 25 carbon atoms, a cycloalkane having 3 to 25 carbon atoms or an aryl group having 3 to 25 carbon atoms, preferably R³ is a straight alkylene chain or alkoxylene chain having 1 to 15 carbon atoms, more preferably 1 to 5 carbon atoms,
which may be substituted by one or more radicals R^{a}, where one or more non-adjacent CH₂ groups may be replaced by R^{a}C═CR^{a}, C═C, Si(R^{a})₂, Ge(R^{a})₂, Sn(R^{a})₂, C═O, C═S, C═Se, C═NR^{a}, P(═O)(R^{a}), SO, SO₂, NR^{a}, OS, or CONR^{a} and where one or more H atoms may be replaced by D, F, Cl, Br, I, CN or NO₂;
R⁴ is a straight alkylene chain or alkoxylene chain having 1 to 25 carbon atoms, a cycloalkane having 3 to 25 carbon atoms or an aryl group having 3 to 25 carbon atoms, preferably R⁴ is a straight alkylene chain or alkoxylene chain having 1 to 15 carbon atoms, more preferably 1 to 5 carbon atoms,
which may be substituted by one or more radicals R^{a}, where one or more non-adjacent CH₂ groups may be replaced by R^{a}C═CR^{a}, C═C, Si(R^{a})₂, Ge(R^{a})₂, Sn(R^{a})₂, C═O, C═S, C═Se, C═NR^{a}, P(═O)(R^{a}), SO, SO₂, NR^{a}, OS, or CONR^{a} and where one or more H atoms may be replaced by D, F, CI, Br, I, CN or NO₂;
R^{a} is at each occurrence, identically or differently, H, D or an alkyl group having 1 to 20 carbon atoms, cyclic alkyl or alkoxy group having 3 to 40 carbon atoms, an aromatic ring system having 5 to 60 carbon ring atoms, or a hetero aromatic ring system having 5 to 60 carbon atoms, wherein H atoms may be replaced by D, F, Cl, Br, I; two or more adjacent substituents R^{a} here may also form a mono- or polycyclic, aliphatic, aromatic or heteroaromatic ring system with one another;

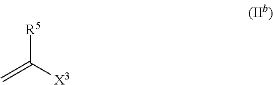

X³ is a non-substituted or substituted ester group, alkyl group, cyclo-alkyl group, aryl group or an alkoxy group, in case of X³ is a non-substituted or substituted ester group, said ester group is represented by following formula (II^{bs}).

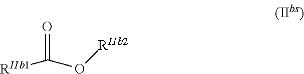

wherein R^{IIb1} is a single bond, a non-substituted or substituted alkylene chain having carbon atoms 1 to 5;
R^{IIb2} is a substituted or non-substituted alkyl group, cyclo group, cyclo-alkyl group, aryl group or an alkoxy group.
preferably the symbol X³ is an ester group of formula (II^{bs}) or

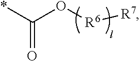

where “*” on the left side of the formula above represents the connecting point to the end group C═CR⁵ of the formula (I);
I is 0 or 1;
R⁵ is a hydrogen atom, halogen atom of Cl, Br, or F, methyl group, alkyl group, aryl group, alkoxy group, ester group, or a carboxylic acid group;
R⁶ is a straight alkylene chain or alkoxylene chain having 1 to 25 carbon atoms, preferably R⁶ is a straight alkylene chain or alkoxylene chain having 1 to 15 carbon atoms, more preferably 1 to 5 carbon atoms, which may be substituted by one or more radicals R^{a}, where one or more non-adjacent CH₂ groups may be replaced by R^{a}C═CR^{a}, C═C, Si(R^{a})₂, Ge(R^{a})₂, Sn(R^{a})₂, C═O, C═S, C═Se, C═NR^{a}, P(═O)(R^{a}), SO, SO₂, NR^{a}, OS, or CONR^{a} and where one or more H atoms may be replaced by D, F, Cl, Br, I, CN or NO₂;
R⁷ is a straight alkylene chain or alkoxylene chain having 1 to 25 carbon atoms, preferably R⁷ is a straight alkylene chain or alkoxylene chain having 1 to 15 carbon atoms, more preferably 1 to 5 carbon atoms, which may be substituted by one or more radicals R^{a}, where one or more non-adjacent CH₂ groups may be replaced by R^{a}C═CR^{a}, C═C, Si(R^{a})₂, Ge(R^{a})₂, Sn(R^{a})₂, C═O, C═S, C═Se, C═NR^{a}, P(═O)(R^{a}), SO, SO₂, NR^{a}, OS, or CONR^{a} and where one or more H atoms may be replaced by D, F, CI, Br, I, CN or NO₂;
R^{a} is at each occurrence, identically or differently, H, D or an alkyl group having 1 to 20 carbon atoms, cyclic alkyl or alkoxy group having 3 to 40 carbon atoms, an aromatic ring system having 5 to 60 carbon ring atoms, or a hetero aromatic ring system having 5 to 60 carbon atoms, wherein H atoms may be replaced by D, F, Cl, Br, I; two or more adjacent substituents R^{a} here may also form a mono- or polycyclic, aliphatic, aromatic or heteroaromatic ring system with one another.

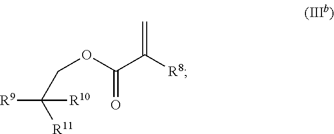

wherein R⁹ is hydrogen atom, a straight alkyl group having 1 to 25 carbon atoms or a (meth)acryl group represented by chemical formula (IV^{b})

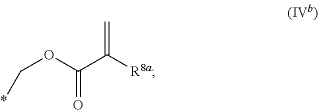

R¹⁰ is hydrogen atom, a straight alkyl group having 1 to 25 carbon atoms or a (meth)acryl group represented by chemical formula (V^{b})

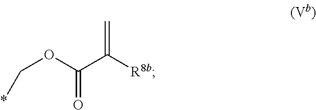

R¹¹ is hydrogen atom, a straight alkyl group having 1 to 25 carbon atoms or a (meth)acryl group represented by chemical formula (VI^{b})

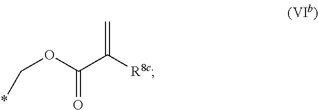

wherein R⁸, R^{8a}, R^{8b} and R^{8c} are, each independently or dependently of each other at each occurrence, H, CH₃ or CH₂CH₃;
wherein at least one of R⁹, R¹⁰ and R¹¹ is a (meth)acryl group, preferably two of R⁹, R¹⁰ and R¹¹ are a (meth)acryl group and other one is a hydrogen atom or a straight alkyl group having 1 to 25 carbon atoms, preferably the electric conductivity (S/cm) of the (meth)acrylate monomer of formula (III) is 1.0*10⁻¹⁰ or less, preferably it is 5.0*10⁻¹¹ or less, more preferably it is in the range from 5.0*10⁻¹¹ to 1.0*10⁻¹⁵, even more preferably it is in the range from 5.0*10⁻¹² to 1.0*10⁻¹⁵.

More preferably, said reactive monomer is represented by the chemical formula (II).

In a preferable embodiment, the monomer mixture of the composition comprises a(meth)acrylate monomer of chemical formula (II) and another (meth)acrylate monomer selected from the (meth)acrylate monomer of chemical formula (I) and/or a (meth)acrylate monomer of chemical formula (III).

In a preferred embodiment of the present invention, the (meth)acrylate monomer of chemical formula (II) is in the composition and the mixing ratio of the (meth)acrylate monomer of chemical formula (I) to the (meth)acrylate monomer of chemical formula (II) is in the range from 1:99 to 99:1 (formula (I): formula (II)), preferably from 5:95 to 50:50, more preferably from 10:90 to 40:60, even more preferably it is from 15:85 to 40:60, preferably at least a purified (meth)acrylate monomer represented by chemical formula (I), (II) is used in the composition, more preferably the (meth)acrylate monomer of chemical formula (I) and the (meth)acrylate monomer of chemical formula (II) are both obtained or obtainable by a purification method.

In a preferred embodiment, the boiling point (B.P.) of said (meth)acrylate monomer of chemical formula (I) and/or chemical formula (II) is 95° C. or more, preferably the (meth)acrylate monomers of chemical formula (I) and chemical formula (II) are both 100° C. or more, more preferably it is in the range from 100° C. to 350° C., even more preferably the boiling point (B.P.) of the (meth)acrylate monomers of chemical formula (I) is in the range from 100° C. to 300° C. and the boiling point (B.P.) of the (meth)acrylate monomers of chemical formula (II) is in the range from 150° C. to 320° C.

In a preferred embodiment of the present invention, the viscosity of the composition is 35 cP or less at room temperature, preferably in the range from 1 to 35 cP, more preferably from 2 to 30 cP, even more preferably from 2 to 25 cP.

According to the present invention, said viscosity can be measured by vibration type viscometer VM-10A (SEKONIC) at room temperature. https://www.sekonic.co.jp/english/product/viscometer/vm/vm_series.html

### (Meth)Acrylate Monomer Represented by Chemical Formula (I) as a Matrix Material

Furthermore preferably, R^{Ib1} of (I^{bs1}) is a single bond, R^{Ibs1} of (I^{bs2}) is a single bond, R^{Ib2} of (I^{bs1}) is a non-substituted or substituted branched alkylene chain having carbon atoms 3 to 7, R^{1bs2} is a single bond, a non-substituted straight alkylene chain having carbon atoms 1 to 5, a non-substituted branched alkylene chain having carbon atoms 3 to 7, where one or more non-adjacent CH₂ groups may be replaced by oxygen atom; or said R³ of formula (I) and R⁴ of formula (I) are, each independently of each other, selected from the following groups.

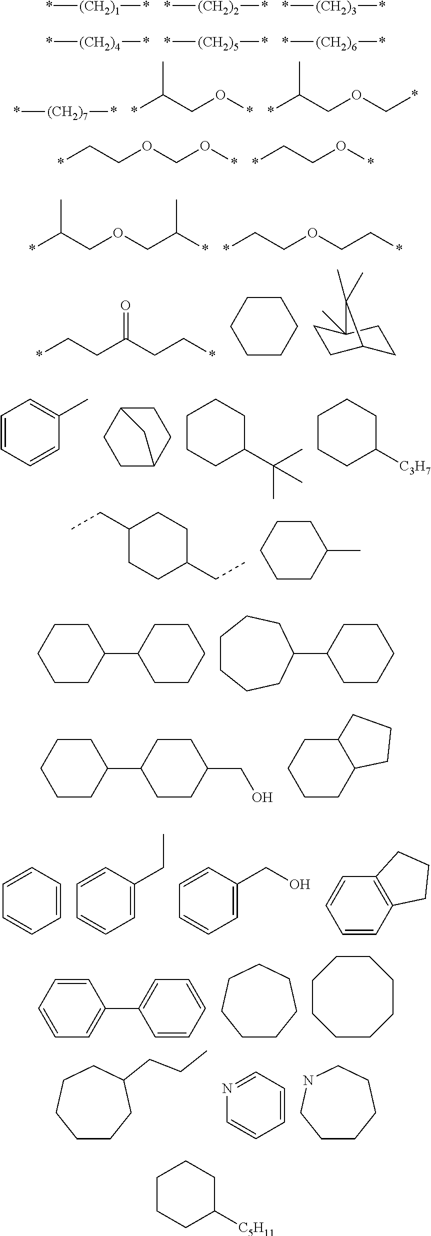

Particularly preferably, said R³ and R⁴ of formula (I) are, at each occurrence, independently or differently, selected from the following groups.

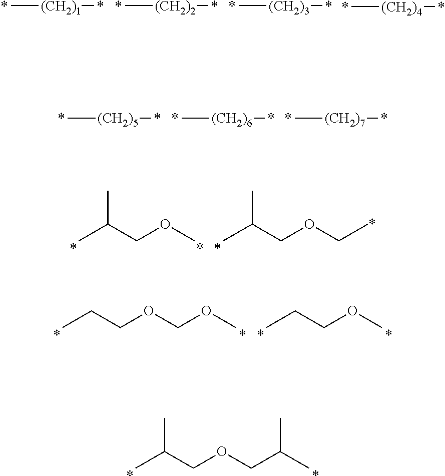

wherein represents the connecting point to oxygen atom of the formula or the connecting point to X² of the formula in case of R³, and wherein represents the connecting point to oxygen atom of the formula or the connecting point to X¹ of the formula in case of R⁴.

Particularly preferably, said formula (I) is NDDA (nonanediol diacrylate), HDDMA (hexanediol dimethacrylate), HDDA (hexanediol diacrylate) or DPGDA ( ), DPGDA=di-propyleneglycol di-acrylate.

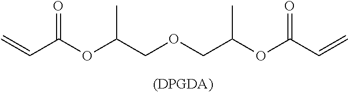 [SMILES: C=CC(=O)OC(C)COCC(C)OC(=O)C=C]

(Meth)acrylate monomer represented by chemical formula (II) It is believed that the (meth)acrylate monomer represented by following chemical formula (II) shows much lower viscosity value than the viscosity of the (meth)acrylate monomer of formula (I). Thus, by using the (meth)acrylate monomer represented by chemical formula (II) in combination of the (meth)acrylate monomer of chemical formula (I), a composition having much lower viscosity desirable for smooth inkjet printing can be realized, preferably without decreasing External Quantum Efficiency (EQE) value.

It is believed that said combination can realize a low viscosity composition comprising high amount of another materials, such as high loading of semiconducting light emitting nanoparticles. Thus, it is especially suitable for an inkjet printing when the composition comprises another material.

Furthermore preferably, R^{IIb1} of (II^{bs}) is a single bond, R^{IIb2} of (II^{bs}) is a substituted or non-substituted alkyl group, cyclo group, cyclo-alkyl group, R^{IIb2} of (II^{bs}) can be selected from the following groups.

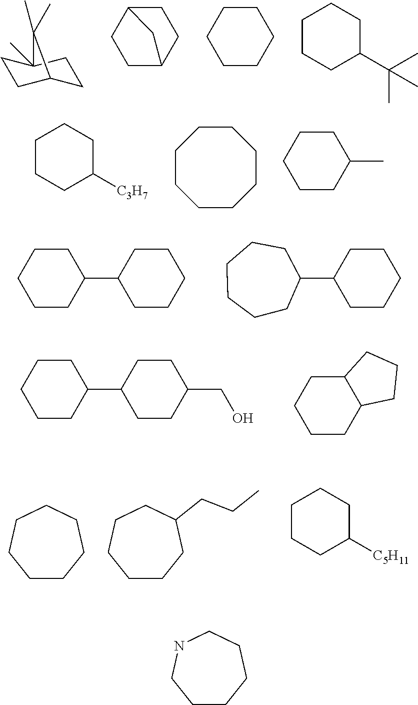

or said R⁷ of formula (II) is, at each occurrence, independently or differently, selected from the following groups, wherein the groups can be substituted with R^{a}, preferably they are unsubstituted by R^{a}.

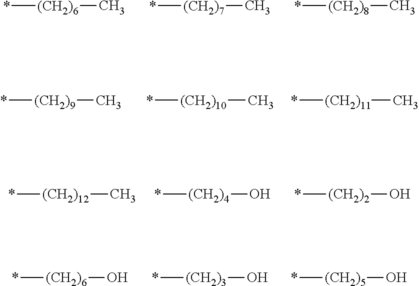

wherein “*” represents the connecting point to R⁶ of X³ in case I is 1, and it is representing the connecting point to oxygen atom of X³ of the formula (II) in case n is 0.

Particularly preferably, said formula (II) is Lauryl methacrylate (LM, viscosity 6 cP) or Lauryl acrylate (LA, viscosity: 4.0 cP) or isobornyl acrylate (IBOA).

It is believed that the higher amount of the (meth)acrylate monomer of chemical formula (II) to the total amount of the (meth)acrylate monomer of chemical formula (I) leads improved EQE of the composition, and the mixing weight ratio of the (meth)acrylate monomer of chemical formula (II) to the total amount of the (meth)acrylate monomer of chemical formula (I) more than 50 wt. % is preferable from the view point of viscosity of the composition, better ink-jetting properties of the composition.

Preferably, (meth)acrylate monomers purified by using silica column are used.

It is believed that an impurity removal from the (meth)acrylate monomers by the silica column purification leads improved QY of the semiconducting light emitting nanoparticle in the composition.

### (Meth)Acrylate Monomer of Chemical Formula (III)

It is believed that the (meth)acrylate monomer of chemical formula (III) is useful to improve its solidity of a later made from the composition after inkjet printing.

According to the present invention, a publicly known a (meth)acrylate monomer represented by following chemical formula (III) can be used to improve solidity of a layer after inkjet printing and cross linking.

Very preferably, Trimethylolpropane Triacrylate (TMPTA) is used as the (meth)acrylate monomer of chemical formula (III).

In a preferable embodiment of the present invention, the amount of the (meth)acrylate monomer of chemical formula (III) based on the total amount of (meth)acrylate monomers in the composition is in the range from 0.001 wt. % to 25 wt. %, more preferably in the range from 0.1 wt. % to 15 wt. %, even more preferably from 1 wt. % to 10 wt. %.

Preferably, there (meth)acrylate monomers are purified by using silica column, are used.

It is believed that an impurity removal from the (meth)acrylate monomers by the silica column purification leads improved QY of the semiconducting light emitting nanoparticle in the composition.

### Process

In one aspect, the present invention also relates to a process for preparing the composition comprising, essentially consisting of, or consisting of, at least following steps;
(a) mixing at least a light emitting moiety, preferably said light emitting moiety comprises at least a 1^{st} semiconducting nanomaterial as a core,
with another material to get a reaction mixture, preferably said another material is a solvent;
(b) forming an outer layer onto the outermost surface of the light emitting moiety in the reaction mixture by reacting at least an anion source represented by chemical formula (Va) or chemical formula (Vb) with a metal cation precursor in a reaction mixture;

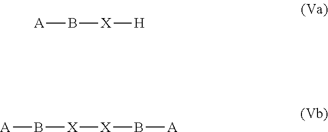

wherein
A is an organic group;
B is a connecting unit;
H is a hydrogen atom; and
X is an anchor group comprising an anion, capable to form a monolayer with the added metal cation derivable from the added metal cation precursor;
(c) cooling the reaction mixture from step (b),
wherein the reaction mixture in step (b) is kept at a temperature in the range from 80° C. to 200° C., preferably from 100 to 200° C. to form the outer layer in step (b),
(d) mixing a light emitting moiety obtained from step (c) with at least one reactive monomer or a mixture of two or more reactive monomers to from a composition.

As an anion source, preferably an organic moiety of chemical formula (II′), (III′), (IIIa′) or (IV′),

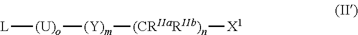

wherein
L is an organic group, preferably said organic group is hydrocarbyl (alkyl, aryl, aralkyl and alkylaryl), heteroaromatic group, including aryl, alkaryl, alkyl or aralkyl, alkylamine, fluoroaryl, fluoroalkaryl, fluoroalkyl, fluoroaralkyl, heteroaromatic group, including fluoroaryl, fluoroalkaryl, fluoroalkyl or fluoroaralkyl;
U is O, CH₂ or C═O;
Y is O, CH₂ or C═O;
R^{IIa} and R^{IIb} are, each independently each other, at each occurrence, selected from hydrogen atom, a hydroxy group, a straight alkyl group having 1 to 10 carbon atoms, a branched alkyl group having 3 to 10 carbon atoms; preferably a hydrogen atom, a hydroxy group, a straight alkyl group having 1 to 5 carbon atoms, a branched alkyl group having 3 to 5 carbon atoms; preferably R^{IIa} and R^{IIb} are hydrogen atom;
n is an integer 1 or more;
m is 0 or an integer 1 or more, preferably m is 1;
o is 0 or an integer 1 or more, preferably o is 1;
X¹ is an anchor group comprising at least a divalent anion being capable to attach to said metal cation preferably by covalent bond, selected from one or more members of the group consisting of Se²⁻, S²⁻, Te²⁻ and O²⁻,

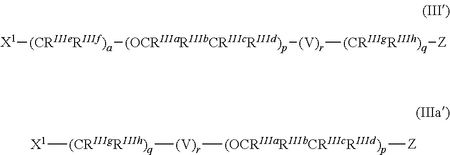

wherein
R^{IIIa}, R^{IIIb}, R^{IIIc}, R^{IIId}, R^{IIIe}, R^{IIIf}, R^{IIIg} and R^{IIIh} are, independently of each other, at each occurrence, selected from hydrogen atom, a hydroxy group, a straight alkyl group having 1 to 10 carbon atoms, a branched alkyl group having 3 to 10 carbon atoms; preferably a hydrogen atom, a hydroxy group, a straight alkyl group having 1 to 5 carbon atoms, a branched alkyl group having 3 to 5 carbon atoms; preferably R^{IIIg} and R^{IIIh} are hydrogen atom, preferably R^{IIIe} and R^{IIIf} are hydrogen atom;
X¹ is an anchor group comprising at least a divalent anion being capable to attach to said metal cation, selected from one or more member of the group consisting of Se²⁻, S²⁻, Te²⁻ and O²⁻;
V is O, CH₂ or C═O;
Z is a hydrogen atom or an organic group, preferably Z is a hydrogen atom, a straight alkyl group having 1 to 25 carbon atoms, a branched alkyl group having 3 to 25 carbon atoms, —COOH, —SH, or —NH₂, alkylamine, fluoroaryl, fluoroalkaryl, fluoroalkyl, fluoroaralkyl, heteroaromatic group, including fluoroaryl, fluoroalkaryl, fluoroalkyl or fluoroaralkyl, preferably Z is a hydrogen atom, a straight alkyl group having 1 to 25 carbon atoms, a branched alkyl group having 3 to 25 carbon atoms, more preferably it is a hydrogen atom, a straight alkyl group having 1-15 carbon atoms, a branched alkyl group having 3-15 carbon atoms, even more preferably it is a hydrogen atom, or a straight alkyl group having 1-10 carbon atoms;
a is 0 or an integer 1 or more, preferably 0≤a≤25, more preferably 0≤a≤15, even more preferably 1≤a≤10;
p is 0 or an integer 1 or more, preferably 0≤p≤45, more preferably 0≤p≤25, even more preferably 1≤p≤20, furthermore preferably 4≤p≤18;
q is 0 or an integer 1 or more, preferably 0≤q≤25, more preferably 0≤q≤15, even more preferably 0≤q≤10, furthermore preferably it is 1≤q≤5;
r is 0 or an integer 1;

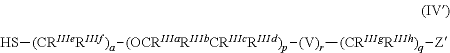

wherein
R^{IIIa}, R^{IIIb}, R^{IIIc}, R^{IIId}, R^{IIIe}, R^{IIIf}, R^{IIIg} and R^{IIIh} are, each independently each other, at each occurrence, selected from hydrogen atom, a hydroxy group, a straight alkyl group having 1 to 10 carbon atoms, a branched alkyl group having 3 to 10 carbon atoms; preferably a hydrogen atom, a hydroxy group, a straight alkyl group having 1 to 5 carbon atoms, a branched alkyl group having 3 to 5 carbon atoms; preferably R^{IIIg} and R^{IIIh} are hydrogen atom, preferably R^{IIIe} and R^{IIIf} are hydrogen atom;
a is 0 or an integer 1 or more, preferably 0≤a≤25, more preferably 0≤a≤15, even more preferably 1≤a≤10;
p is 0 or an integer 1 or more, preferably 0≤p≤45, more preferably 0≤p≤25, even more preferably 1≤p≤20, furthermore preferably 4≤p≤18;
q is 0 or an integer 1 or more, preferably 0≤q≤25, more preferably 0≤q≤15, even more preferably 0≤q≤10, furthermore preferably it is 1;
V is O, CH₂ or C═O;
Z′ is a hydrogen atom a straight alkyl group having 1 to 25 carbon atoms, a branched alkyl group having 3 to 25 carbon atoms, alkylamine, fluoroaryl, fluoroalkaryl, fluoroalkyl, fluoroaralkyl, heteroaromatic group, including fluoroaryl, fluoroalkaryl, fluoroalkyl or fluoroaralkyl, preferably Z′ is a straight alkyl group having 1 to 25 carbon atoms, a branched alkyl group having 3 to 25 carbon atoms or a hydrogen atom, more preferably it is a straight alkyl group having 1-15 carbon atoms, a branched alkyl group having 3-15 carbon atoms or a hydrogen atom, even more preferably it is a hydrogen atom;
r is 0 or an integer 1.

For examples, following materials can be used as the anion source preferably.

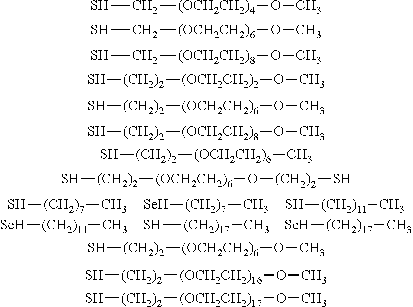

Other thiolated ligand materials like polypropyleneglyco and polypropyleneglycol monomethyl ethwe, thiolated ligand materials described in U.S. Ser. No. 11/021,651 B2, formula (I), formula (II) of column 17-18, line 28 of column 25 to line 16 of column 26, M1000-SH of Example 1 can also be used as a source of organic moiety and the resulting covalently bonded organic moiety is included in this patent application.

It is believed that the temperature ranges from 80° C. to 200° C. is important to make a crystal binding between the organic moiety and the outer layer.

In other words, by keeping the reaction temperature in step (b) within the temperature range, the anchor group of chemical formula (I), (II), (III) and/or (IV) is being attached to a cation to form the outer layer, while the organic moiety is kept attached to the anchor group by covalent bond

In a preferred embodiment of the present invention, an injection of said anion source is carried out at the temperature in the range from 0° C. to 200° C., preferably in the range from 20° C. to 180° C. in step (a) or in step (b).

It is believed that the temperature range of the injection is also important to prevent X—B bond breakage.

Preferably, step (b) is carried out in the range from 1 minute to 10 hours, preferably from 10 minutes to 5 hours, more preferably 20 minutes to 3 hours.

According to the present invention, preferably, the ratio of the total molar amount of the cation precursor to the total molar amount of the semiconducting nanoparticle in step (b) is in the range from 20:1 to 200000:1, preferably from 100:1 to 60000:1, more preferably 110:1 to 58000:1, even more preferably 120:1 to 5000:1.

In a preferred embodiment of the present invention, the ratio of the total molar amount of the chalcogen source to the total molar amount of the semiconducting nanoparticle in step (b) is in the range from 20:1 to 200000:1, preferably from 100:1 to 60000:1, more preferably 110:1 to 58000:1, even more preferably 120:1 to 5000:1. Preferably, the ratio of the total mass amount of the cation precursor to the total mass amount of the semiconducting nanoparticle in step (b) is in the range from 1:1000 to 1:1, preferably from 1:500 to 1:2, more preferably 1:400 to 1:2.

In some embodiments of the present invention, an anion source represented by chemical formula (2), (3) and/or (4) can be used singly or in combination with any other chalcogen source as the anion source in step (b) to form the outer layer.

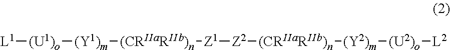

L¹ and L² are each independently or dependently of each other, an organic group, preferably said organic group is a hydrocarbyl (alkyl, aryl, aralkyl and alkylaryl) group, including aryl, alkaryl, alkyl or aralkyl;
R^{IIa} and R^{IIb} are, each independently each other, at each occurrence, selected from hydrogen atom, a hydroxy group, a straight alkyl group having 1 to 10 carbon atoms, a branched alkyl group having 3 to 10 carbon atoms; preferably a hydrogen atom, a hydroxy group, a straight alkyl group having 1 to 5 carbon atoms, a branched alkyl group having 3 to 5 carbon atoms; preferably R^{IIa} and R^{IIb} are hydrogen atom;
n is an integer 1 or more;
m is 0 or an integer 1 or more, preferably m is 1;
o is 0 or an integer 1 or more, preferably o is 1;
U¹ and U² are at each occurrence, independently or dependently of each other, O, —CH₂— or C═O;
Y¹ and Y² are at each occurrence, independently or dependently of each other, O, —CH₂— or C═0;
n is an integer 1 or more;
Z¹ is a divalent anion selected from Se, S, Te, O;
Z² is a divalent anion selected from Se, S, Te, O.

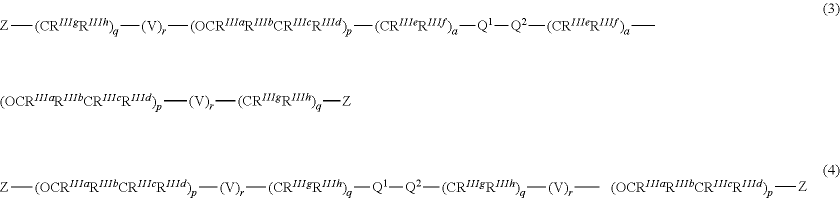

wherein
R^{IIIa}, R^{IIIb}, R^{IIIc}, R^{IIId}, R^{IIIe}, R^{IIIf}, R^{IIIg} and R^{IIIh} are, independently of each other, at each occurrence, selected from hydrogen atom, a hydroxy group, a straight alkyl group having 1 to 10 carbon atoms, a branched alkyl group having 3 to 10 carbon atoms; preferably a hydrogen atom, a hydroxy group, a straight alkyl group having 1 to 5 carbon atoms, a branched alkyl group having 3 to 5 carbon atoms; preferably R^{IIIg} and R^{IIIh} are hydrogen atom, preferably R^{IIIe} and R^{IIIf} are hydrogen atom; V is O, CH₂ or C═O;
Z is a hydrogen atom or an organic group, preferably Z is a hydrogen atom, a straight alkyl group having 1 to 25 carbon atoms, a branched alkyl group having 3 to 25 carbon atoms, —COOH, —SH, or —NH₂, alkylamine, fluoroaryl, fluoroalkaryl, fluoroalkyl, fluoroaralkyl, heteroaromatic group, including fluoroaryl, fluoroalkaryl, fluoroalkyl or fluoroaralkyl, preferably Z is a hydrogen atom, a straight alkyl group having 1 to 25 carbon atoms, a branched alkyl group having 3 to 25 carbon atoms, more preferably it is a hydrogen atom, a straight alkyl group having 1-15 carbon atoms, a branched alkyl group having 3-15 carbon atoms, even more preferably it is a hydrogen atom, or a straight alkyl group having 1-10 carbon atoms;
a is 0 or an integer 1 or more, preferably 0≤a≤25, more preferably 0≤a≤15, even more preferably 1≤a≤10;
p is 0 or an integer 1 or more, preferably 0≤p≤45, more preferably 0≤p≤25, even more preferably 1≤p≤20, furthermore preferably 4≤p≤18;
q is 0 or an integer 1 or more, preferably 0≤q≤25, more preferably 0≤q≤15, even more preferably 0≤q≤10, furthermore preferably it is 1≤q≤5;
r is 0 or an integer 1;
Q¹ and Q2 are, independently of each other, a divalent anion selected from Se, S, Te, O;

For examples, mPEG-S-S-mPEG can be used.

For examples,

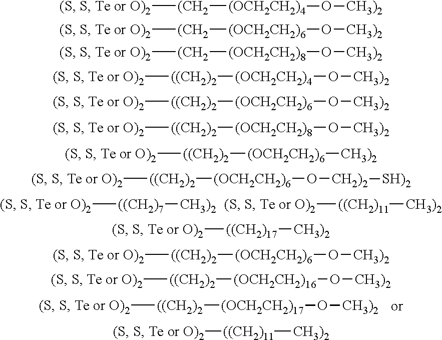

In a preferred embodiment of the present invention, the anion source described by the formula (2), (3) or (4), such as bis-chalcogenides, can be used in step (b) together with a reducing agent to form the outer layer, preferably said reducing agent is represented by secondary phosphines.

In a preferred embodiment of the present invention, the ratio of the molar amount of the anion source and the molar amount of the cation precursor used in step (b) is in the range from 20:1 to 1:20, preferably in the range from 12:1 to 1:12, even more preferably 5:1 to 1:5.

### Chalcogen Source

According to the present invention, the term “chalcogen” means a chemical element of the group 16 chemical elements of the periodic table, preferably it is sulfur (S), selenium (Se), oxygen (O) and/or tellurium (Te)

Thus, according to the present invention, the term “chalcogen source” means a material containing at least one chemical element of the group 16 chemical elements of the periodic table, preferably said chemical element of the group 16 chemical elements is oxygen (O), sulfur (S), selenium (Se), and/or tellurium (Te), more preferably it is sulfur (S), or selenium (Se).

In a preferred embodiment of the present invention, said chalcogen source is a selenium source, sulfur source or a combination of selenium source and a selenium source. More preferably, it is selected from selenols, diselenides, thiols, disulphides or a combination of these,

Step (a)—Mixing

In a preferred embodiment of the present invention, step (a) is carried out in an inert condition such as under Argon (Ar) or N₂ condition, more preferably under Ar condition.

In a preferred embodiment of the present invention, said another material used in step (a) is a solvent, more preferably it is an organic solvent, even more preferably it is selected from one or more members of the group consisting of squalenes, squalanes, heptadecanes, octadecanes, octadecenes, nonadecanes, icosanes, henicosanes, docosanes, tricosanes, pentacosanes, hexacosanes, octacosanes, nonacosanes, triacontanes, hentriacontanes, dotriacontanes, tritriacontanes, tetratriacontanes, pentatriacontanes, hexatriacontanes, oleylamines, trioctylamines, ketones, ketones ether acetates such as PGMEA, nitriles, ethers, etheric esters, aromatic solvents such as toluene, xylenes, ethylbenzene, diethylbenzes, isopropylbenzene, diisopropylbenzenes, mesitylene, with preferably being of squalene, squalane, heptadecane, octadecane, octadecene, nonadecane, icosane, henicosane, docosane, tricosane, pentacosane, hexacosane, octacosane, tetracosane, nonacosane, triacontane, hentriacontane, dotriacontane, tritriacontane, tetratriacontane, pentatriacontane, hexatriacontane, oleylamine, trioctylamines, ketones, ketones ether acetates such as PGMEA, nitriles, ethers, aromatic solvents such as toluene, xylenes, ethylbenzene, diethylbenzes, isopropylbenzene, diisopropylbenzenes, mesitylene, more preferably octadecenes, oleylamine, squalane, pentacosane, hexacosane, octacosane, nonacosane, trioctylamine or triacontane, ketones, ketones, ether acetates such as PGMEA, nitriles, ethers, etheric esters, aromatic solvents such as toluene, xylenes, ethylbenzene, diethylbenzes, isopropylbenzene, diisopropylbenzenes, mesitylene, even more preferably octadecene, oleylamine, squalane, pentacosane, trioctylamine or hexacosane, tetracosane, ketones, ketones ether acetates such as PGMEA, etheric esters, nitriles, ethers, aromatic solvents such as toluene, xylenes, ethylbenzene, diethylbenzes, isopropylbenzene, diisopropylbenzenes, mesitylene.

In a preferred embodiment of the present invention, said mixing step is carried out at the temperature in the range of from 0° C. to 100° C., preferably from 5 to 60° C., more preferably from 10 to 40° C.

Light emitting moieties, preferably a light emitting moiety comprises at least a 1^{st} semiconducting nanomaterial as a core, can be obtained from public source or obtained as described for example in U.S. Pat. No. 8,679,543 B2, WO 2020/216813 A and Chem. Mater. 2015, 27, pp 4893-4898.

In a preferred embodiment of the present invention, said cation shell precursor is a salt of an element of the group 12 of the periodic table, more preferably said cation shell precursor is selected from one or more members of the group consisting of Zn-stearate, Zn-isostearate, Zn-myristate, Zn-oleate, Zn-laurate, Zn-palmitate, Zn-acetylacetonate, Zn-undecylenate, Zn-Acetate, Cd-stearate, Cd-myristate, Cd-oleate, Cd-laurate, Cd-palmitate, Cd-acetylacetonate, Cd-undecylenate, Cd-acetate, a metal halogen represented by chemical formula (XIII) and a metal carboxylate represented by chemical formula (XIV),

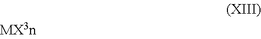

wherein M is Zn²⁺, or Cd²⁺, preferably M is Zn²⁺, X³ is a halogen selected from the group consisting of F−, Cl⁻, Br⁻ and I⁻, n is 2,

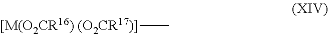

wherein M is Zn²⁺, or Cd²⁺, preferably M is Zn²⁺,
R¹⁶ is a linear alkyl group having 1 to 30 carbon atoms, a branched alkyl group having 3 to 30 carbon atoms, a linear unsaturated hydrocarbyl group having 2 to 30 carbon atoms, or a branched unsaturated hydrocarbyl group having 3 to 30 carbon atoms, preferably R¹⁶ is a linear alkyl group having 1 to 30 carbon atoms, or a linear unsaturated hydrocarbyl group having 2 to 30 carbon atoms, more preferably, R¹⁶ is a linear alkyl group having 2 to 25 carbon atoms, or a linear unsaturated hydrocarbyl group having 6 to 25 carbon atoms, even more preferably R¹⁶ is a linear alkyl group having 2 to 20 carbon atoms, or a linear unsaturated hydrocarbyl group having 10 to 20 carbon atoms, furthermore preferably R¹⁶ is a linear alkyl group having 2 to 20 carbon atoms,
R¹⁷ is a linear alkyl group having 1 to 30 carbon atoms, a branched alkyl group having 3 to 30 carbon atoms, a linear unsaturated hydrocarbyl group having 2 to 30 carbon atoms, or a branched unsaturated hydrocarbyl group having 43 to 30 carbon atoms, preferably R¹⁷ is a linear alkyl group having 1 to 30 carbon atoms, or a linear unsaturated hydrocarbyl group having 2 to 30 carbon atoms, more preferably R¹⁷ is a linear alkyl group having 2 to 25 carbon atoms, or a linear unsaturated hydrocarbyl group having 6 to 25 carbon atoms, even more preferably R¹⁷ is a linear alkyl group having 2 to 20 carbon atoms, or a linear unsaturated hydrocarbyl group having 10 to 20 carbon atoms, furthermore preferably R¹⁷ is a linear alkyl group having 2 to 20 carbon atoms.

In a preferred embodiment, R¹⁶ and R¹⁷ are the same.

In a preferred embodiment of the present invention, the molar ratio of the total amount of the chalcogen source, preferably said chalcogen source is a selenium source, sulfur source or a combination of selenium source and a sulfur source, and the total amount of the cation shell precursor used in step (b) is in the range from 20:1 to 1:20, preferably in the range from 12:1 to 1:12.

### Cooling Step (c)

According to the present invention, cooling the reaction mixture from step (b) is carried out in step (c) to stop forming reaction accordingly.

As a cooling method, several methods can be used singly or in combination. Such as removing a heat source, injecting a solvent such as a solvent at a room temperature, and/or applying air cooling.

In a preferred embodiment, the reaction mixture is cooled down to 50° C. or less and above 0° C. preferably to a room temperature.

After cooling, the resulted light emitting moiety can be cleaned by a known method and preferably centrifuged. Solids in the reaction mixture from step (c) can be removed by centrifugation. Then cleaned light emitting moiety can be used in step (d).

### Formulation

In another aspect, the present invention may relate to formulation comprising, essentially consisting of, or consisting of, at least the composition of the present invention, and at least one solvent.

Preferably the solvent is selected from one or more members of the group consisting of aromatic, halogenated and aliphatic hydrocarbon solvents or alcohols or ethers or ketons or water, more preferably selected from one or more members of the group consisting of toluene, xylene, ethers, tetrahydrofuran, chloroform, dichloromethane and heptane, purified water, ester acetates, alcohols, sulfoxides, formamides, nitrides, ketones, ether acetates.

The amount of the solvent in the formulation can be freely controlled according to the method of coating the composition. For example, if the composition is to be spray-coated, it can contain the solvent in an amount of 90 wt. % or more. Further, if a slit-coating method, which is often adopted in coating a large substrate, is to be carried out, the content of the solvent is normally 60 wt. % or more, preferably 70 wt. % or more.

In some embodiments, the formulation may only contain Swt % or less solvent based on the total amount of the composition. Preferably the composition does not contain any solvent.

### Use

In another aspect, the present invention also relates to use of the composition or the formulation in an electronic device, optical device, sensing device or in a biomedical device.

### Method for Forming a Layer

In another aspect, the present invention also relates to a method for forming a layer comprising:
S1) providing the composition onto a substrate, preferably by ink-jetting,
S2) curing the composition, preferably said curing is a photo curing performed by photo irradiation, thermal curing or a combination of a photo curing and a thermal curing.

### Layer

In another aspect, the present invention also relates to a layer obtained or obtainable from the method of the present invention.

In another aspect, the present invention also relates to a layer containing at least, essentially consisting of or consisting of;
Xi) a light emitting moiety, preferably it is a semiconducting light emitting nanoparticle, comprising an outer layer containing a metal cation and a divalent anion; and
one or more types of organic moieties directly attached to the anion of the outer layer by covalent bond,
Xii) a polymer made from at least one reactive monomer or a mixture of two or more reactive monomers, preferably said monomer having one or more of functional groups, more preferably it is a(meth)acrylate monomer;
wherein said divalent anion of the outer layer is selected from Se²⁻, S²⁻, Te²⁻O²⁻ or a combination of any of these, preferably said metal cation of the outer layer is a monovalent, divalent, trivalent or tetravalent cation, more preferably said metal cation is a divalent cation selected from the group consisting of Zn²⁺, Ni²⁺, Co²⁺, Ca²⁺, Sr²⁺, Hg²⁺, Mg²⁺ and Pb²⁺, or a tetravalent cation selected from the group consisting of Ti⁴⁺, Ge⁴⁺, Si⁴⁺, Zr⁴⁺, Hf⁴⁺, and Sn⁴⁺.

### Color Conversion Device (100)

In another aspect, the present invention also relates to a color conversion device (100) comprising at least, essentially consisting of or consisting of; a 1^{st} pixel (161) partly or fully filled with the layer of any one of claims 20 to 22 and 24 comprising at least a matrix material (120) containing a light emitting moiety (110), and a bank (150) comprising at least a polymer material, preferably the color conversion device (100) further contains a supporting medium (170).

### 1^{st} Pixel (161)

According to the present invention, said 1^{st} pixel (161) comprises at least a matrix material (120) containing a light emitting moiety (110). In a preferable embodiment, the 1^{st} pixel (161) is a solid layer obtained or obtainable by curing the composition of the present invention containing at least one acrylate monomer together with at least one light emitting moiety (110), preferably said curing is a photo curing by photo irradiation, thermal curing or a combination of a photo curing and a thermal curing.

In some embodiments of the present invention, the layer thickness of the pixel (161) is in the range from 0.1 to 100 μm, preferably it is from 1 to 50 μm, more preferably from 5 to 25 μm.

In some embodiments of the present invention, the color conversion device (100) further contains a 2^{nd} pixel (162), preferably the device (100) contains at least said 1^{st} pixel (161), 2^{nd} pixel (162) and a 3^{rd} pixel (163), more preferably said 1^{st} pixel (161) is a red color pixel, the 2^{nd} pixel (162) is a green color pixel and the 3^{rd} pixel (163) is a blue color pixel, even more preferably the 1^{st} pixel (161) contains a red light emitting moiety (110R), the 2^{nd} color pixel (162) contains a green light emitting moiety (110G) and the 3^{rd} pixel (163) does not contain any light emitting moiety.

In some embodiments, at least one pixel (160) additionally comprises at least one light scattering particle (130) in the matrix material (120), preferably the pixel (160) contains a plurality of light scattering particles (130).

In a preferable embodiment, said 1^{st} pixel (161) consists of one pixel or two or more sub-pixels configured to emit red-color when irradiated by an excitation light, more preferably said sub-pixels contains the same light emitting moiety (110).

### Matrix Material (120)

In a preferable embodiment, the matrix material (120) contains a (meth)acrylate polymer, preferably it is a methacrylate polymer, an acrylate polymer or a combination of thereof, more preferably it is an acrylate polymer, even more preferably said matrix material (120) is obtained or obtainable from the composition of the present invention containing at least one acrylate monomer, further more preferably said matrix material (120) is obtained or obtainable from the composition of the present invention containing at least one di-acrylate monomer, particularly preferably said matrix material (120) is obtained or obtainable from the composition of the present invention containing at least one di-acrylate monomer and a mono-acrylate monomer, preferably said composition is a photosensitive composition.

### Bank (150)

In some embodiments of the present invention, the height of the bank (150) is in the range from 0.1 to 100 μm, preferably it is from 1 to 50 μm, more preferably from 1 to 25 μm, furthermore preferably from 5 to 20 μm.

In a preferred embodiment of the present invention, the bank (150) is configured to determine the area of said 1^{st} pixel (161) and at least a part of the bank (150) is directly contacting to at least a part of the 1^{st} pixel (161), preferably said 2^{nd} polymer of the bank (150) is directly contacting to at least a part of the 1^{st} polymer of the 1^{st} pixel (161).

More preferably, said bank (150) is photolithographically patterned and said 1^{st} pixel (161) is surrounded by the bank (150), preferably said 1^{st} pixel (161), the 2^{nd} pixel (162) and the 3^{rd} pixel (163) are all surrounded by the photolithographically patterned bank (150).

In another aspect, the present invention also relates to a method for fabricating a color conversion device (100) of the present invention, containing at least the following steps, preferably in this sequence,
Xi) Providing a bank composition onto a surface of a supporting medium
Xii) Curing the bank composition,
Xiii) Applying photo-patterning to the cured said composition to fabricate bank and a patterned pixel region,
Xiv) Providing the composition of the present invention to at least one pixel region, preferably by ink-jetting,
Xv) Curing the composition, preferably said color conversion device (100) further contains a supporting medium (170).

In another aspect, the present invention further relates to a color conversion device (100) obtainable or obtained from the method of the present invention.

In another aspect, the present invention further relates to use of the color conversion device (100) of the present invention in an optical device (300) containing at least one functional medium (320, 420, 520) configured to modulate a light or configured to emit light.

Further, in another aspect, the present invention further relates to an optical device (300) containing at least, essentially consisting of or consisting of, one functional medium (320, 420, 520) configured to modulate a light or configured to emit light, and the color conversion device (100) of the present invention.

In some embodiments of the present invention, said optical device can be a liquid crystal display device (LCD), Organic Light Emitting Diode (OLED), Light Emitting Diode device (LED), Micro LED, Micro Electro Mechanical Systems (here in after “MEMS”), electro wetting display, or an electrophoretic display.

Therefore, in a preferred embodiment, said functional medium can be a LC layer, OLED layer, LED layer, micro LED layer, MEMS layer, electro wetting layer and/or an electrophoretic layer. More preferably it is a LC layer, micro LED layer or an OLED layer.

### PREFERABLE EMBODIMENTS

1. A composition, preferably it is being of a photocurable composition, comprising at least;
i) a light emitting moiety, preferably it is a semiconducting light emitting nanoparticle, comprising an outer layer containing a metal cation and a divalent anion; and
one or more types of organic moieties directly attached to the anion of the outer layer by covalent bond,
ii) at least one reactive monomer or a mixture of two or more reactive monomers, preferably said monomer having one or more of functional groups, more preferably it is a (meth)acrylate monomer;
wherein said divalent anion of the outer layer is selected from Se²⁻, S²⁻, Te²⁻O²⁻ or a combination of any of these, preferably said metal cation of the outer layer is a monovalent, divalent, trivalent or tetravalent cation, more preferably said metal cation is a divalent cation selected from the group consisting of Zn²⁺, Ni²⁺, Co²⁺, Ca²⁺, Sr²⁺, Hg²⁺, Mg²⁺ and Pb²⁺, or a tetravalent cation selected from the group consisting of Ti⁴⁺, Ge⁴⁺, Si⁴⁺, Zr⁴⁺Hf⁴⁺, and Sn⁴⁺.

2. The composition of embodiment 1, wherein the organic moiety is represented by following chemical formula (I);

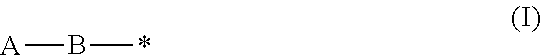

wherein
A is an organic group, preferably said organic group is hydrocarbyl (alkyl, aryl, aralkyl and alkylaryl), heteroaromatic group, including aryl, alkaryl, alkyl or aralkyl, alkylamine, fluoroaryl, fluoroalkaryl, fluoroalkyl, fluoroaralkyl, heteroaromatic group, including fluoroaryl, fluoroalkaryl, fluoroalkyl or fluoroaralkyl;
B is a connecting unit, preferably B is **-(U)ₒ-(Y)ₘ-(CR^{11a}R^{IIb})ₙ wherein represents the connecting point to “A;” and
“*” represents the connecting point to the anion in the outer layer.

3. The composition of embodiment 1 or 2, wherein the organic moiety is represented by following chemical formula (II), (III) or (III′);

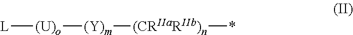

wherein
L is an organic group, preferably said organic group is hydrocarbyl (alkyl, aryl, aralkyl and alkylaryl), heteroaromatic group, including aryl, alkaryl, alkyl or aralkyl, alkylamine, fluoroaryl, fluoroalkaryl, fluoroalkyl, fluoroaralkyl, heteroaromatic group, including fluoroaryl, fluoroalkaryl, fluoroalkyl or fluoroaralkyl;
U is O, CH₂ or C═O;
Y is O, CH₂ or C═O;
R^{11a} and R^{IIb} are, each independently each other, at each occurrence, selected from hydrogen atom, a hydroxy group, a straight alkyl group having 1 to 10 carbon atoms, a branched alkyl group having 3 to 10 carbon atoms; preferably a hydrogen atom, a hydroxy group, a straight alkyl group having 1 to 5 carbon atoms, a branched alkyl group having 3 to 5 carbon atoms; preferably R^{11a} and R^{IIb} are hydrogen atom;
n is an integer 1 or more;
m is 0 or an integer 1 or more, preferably m is 1;
o is 0 or an integer 1 or more, preferably o is 1;
“*” represents the connecting point to the anion in the outer layer;

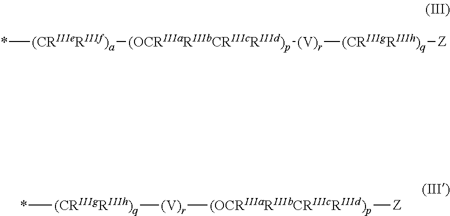

wherein
R^{IIIa}, R^{IIIb}, R^{IIIc}, R^{IIId}, R^{IIIe}, R^{IIIf}, R^{IIIg} and R^{IIIh} are, each independently each other, at each occurrence, selected from hydrogen atom, a hydroxy group, a straight alkyl group having 1 to 10 carbon atoms, a branched alkyl group having 3 to 10 carbon atoms; preferably a hydrogen atom, a hydroxy group, a straight alkyl group having 1 to 5 carbon atoms, a branched alkyl group having 3 to 5 carbon atoms; preferably R^{IIIg} and R^{IIIh} are hydrogen atom, preferably R^{IIIe} and R^{IIIf} are hydrogen atom; V is O, CH₂ or C═O;
Z is a hydrogen atom or an organic group, preferably Z is a hydrogen atom, a straight alkyl group having 1 to 25 carbon atoms, a branched alkyl group having 3 to 25 carbon atoms, —COOH, —SH, or —NH₂, alkylamine, fluoroaryl, fluoroalkaryl, fluoroalkyl, fluoroaralkyl, heteroaromatic group, including fluoroaryl, fluoroalkaryl, fluoroalkyl or fluoroaralkyl, preferably Z is a hydrogen atom, a straight alkyl group having 1 to 25 carbon atoms, a branched alkyl group having 3 to 25 carbon atoms, more preferably it is a hydrogen atom, a straight alkyl group having 1-15 carbon atoms, a branched alkyl group having 3-15 carbon atoms, even more preferably it is a hydrogen atom, or a straight alkyl group having 1-10 carbon atoms;
a is 0 or an integer 1 or more, preferably 0≤a≤25, more preferably 0≤a≤15, even more preferably 1≤a≤10;
p is 0 or an integer 1 or more, preferably 0≤p≤45, more preferably 0≤p≤25, even more preferably 1≤p≤20, furthermore preferably 4≤p≤18;
q is 0 or an integer 1 or more, preferably 0≤q≤25, more preferably 0≤q≤15, even more preferably 0≤q≤10, furthermore preferably it is 1≤q≤5;
r is 0 or an integer 1;
“*” represents the connecting point to the anion in the outer layer.

4. The composition of any one of the preceding embodiments, wherein the organic moiety is represented by following chemical formula (IV):

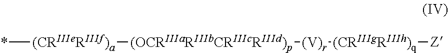

wherein
R^{IIIa}, R^{IIIb}, R^{IIIc}, R^{IIId}, R^{IIIe}, R^{IIIf}, R^{IIIg} and R^{IIIh} are, each independently each other, at each occurrence, selected from hydrogen atom, a hydroxy group, a straight alkyl group having 1 to 10 carbon atoms, a branched alkyl group having 3 to 10 carbon atoms; preferably a hydrogen atom, a hydroxy group, a straight alkyl group having 1 to 5 carbon atoms, a branched alkyl group having 3 to 5 carbon atoms; preferably R^{IIIg} and R^{IIIh} are hydrogen atom, preferably R^{IIIe} and R^{IIIf} are hydrogen atom;
a is 0 or an integer 1 or more, preferably 0≤a≤25, more preferably 0≤a≤15, even more preferably 1≤a≤10;
p is 0 or an integer 1 or more, preferably 0≤p≤45, more preferably 0≤p≤25, even more preferably 1≤p≤20, furthermore preferably 4≤p≤18;
q is 0 or an integer 1 or more, preferably 0≤q≤25, more preferably 0≤q≤15, even more preferably 0≤q≤10, furthermore preferably it is 1;
V is O, CH₂ or C═O;
Z′ is a hydrogen atom a straight alkyl group having 1 to 25 carbon atoms, a branched alkyl group having 3 to 25 carbon atoms, alkylamine, fluoroaryl, fluoroalkaryl, fluoroalkyl, fluoroaralkyl, heteroaromatic group, including fluoroaryl, fluoroalkaryl, fluoroalkyl or fluoroaralkyl, preferably Z′ is a straight alkyl group having 1 to 25 carbon atoms, a branched alkyl group having 3 to 25 carbon atoms or a hydrogen atom, more preferably it is a straight alkyl group having 1-15 carbon atoms, a branched alkyl group having 3-15 carbon atoms or a hydrogen atom, even more preferably it is a hydrogen atom;
r is 0 or an integer 1;
“*” represents the connecting point to the anion in the outer layer, preferably it is connected to S or Se atom in the outer layer

5. The composition of any one of the preceding embodiments, wherein the organic moiety is covalently bound to the anion in the outer layer of an inorganic lattice, preferably it is not removed by a ligand exchange.

6. The composition of any one of the preceding embodiments, wherein metal cation is a transition metal of group 12 or group 14, preferably it is selected from one or more members of the group consisting of Zn²⁺, Hg²⁺ or Pb²⁺.

7. The composition of any one of the preceding embodiments, wherein said reactive monomer is a (meth)acrylate monomer selected from a mono-(meth)acrylate monomer, a di-(meth)acrylate monomer and/or a tri-(meth)acrylate monomer.

Preferably said two or more reactive monomers of the mixture is each independently selected from a mono-(meth)acrylate monomer, a di-(meth)acrylate monomer and/or a tri-(meth)acrylate monomer.

8. The composition of embodiment 7, said di-(meth)acrylate monomer is represented by following chemical formula (I^{b}), said mono-acrylate monomer is represented by following chemical formula (II^{b}) and/or said tri-(meth)acrylate monomer is represented by following chemical formula (IlI^{b});

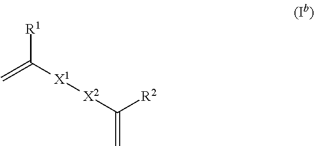

wherein
X¹ is a non-substituted or substituted ester group, alkyl group or aryl group, where one or more non-adjacent CH₂ groups of ester, alkyl or aryl group may be replaced by oxygen atom, C═O, C═S, C═Se, C═NH, SiH₂, SO, SO₂, OS, or CONH and where one or more H atoms may be replaced by D, F, Cl, Br, I, CN or NO₂; preferably said ester group is represented by following formula (I^{bs1});

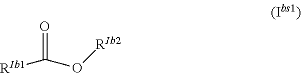

wherein R^{Ib1} is a single bond, a non-substituted or substituted alkylene chain having carbon atoms 1 to 5;
R^{Ib2} is a single bond, a non-substituted or substituted straight alkylene chain having carbon atoms 1 to 5, a non-substituted or substituted branched alkylene chain having carbon atoms 3 to 7, where one or more non-adjacent CH₂ groups may be replaced by oxygen atom, C═O, C═S, C═Se, C═NH, SiH₂, SO, SO₂, OS, or CONH and where one or more H atoms may be replaced by D, F, Cl, Br, I, CN or NO₂; preferably R^{Ib2} is a non-substituted or substituted branched alkylene chain having carbon atoms 3 to 7, where at least one of non-adjacent CH₂ groups may be replaced by oxygen atom, C═O, C═S, C═Se, C═NH, SiH₂, SO, SO₂, OS, or CONH and where one or more H atoms may be replaced by D, F, Cl, Br, I, CN or NO₂; Furthermore preferably, R^{Ib1} of (I^{bs1}) is a single bond, R^{Ibs1} of (I^{bs2}) is a single bond, R^{Ib2} of (I^{bs1}) is a non-substituted or substituted branched alkylene chain having carbon atoms 3 to 7, R^{Ibs2} is a single bond, a non-substituted straight alkylene chain having carbon atoms 1 to 5, a non-substituted branched alkylene chain having carbon atoms 3 to 7, where one or more non-adjacent CH₂ groups may be replaced by oxygen atom;
X² is a non-substituted or substituted non-substituted or substituted ester group, alkyl group or aryl group, where one or more non-adjacent CH₂ groups of ester, alkyl or aryl group may be replaced by oxygen atom, C═O, C═S, C═Se, C═NH, SiH₂, SO, SO₂, OS, or CONH and where one or more H atoms may be replaced by D, F, Cl, Br, I, CN or NO₂; preferably said ester group is represented by following formula (I^{bs2});

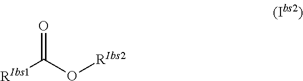

wherein R^{Ibs1} is a single bond, a non-substituted or substituted alkylene chain having carbon atoms 1 to 5;
R^{Ibs2} is a single bond, a non-substituted or substituted straight alkylene chain having carbon atoms 1 to 5, a non-substituted or substituted branched alkylene chain having carbon atoms 3 to 7, where one or more non-adjacent CH₂ groups may be replaced by oxygen atom, C═O, C═S, C═Se, C═NH, SiH₂, SO, SO₂, OS, or CONH and where one or more H atoms may be replaced by D, F, Cl, Br, I, CN or NO₂; preferably R^{Ib2} is a non-substituted or substituted branched alkylene chain having carbon atoms 3 to 7, where at least one of non-adjacent CH₂ groups may be replaced by oxygen atom, C═O, C═S, C═Se, C═NH, SiH₂, SO, SO₂, OS, or CONH and where one or more H atoms may be replaced by D, F, Cl, Br, I, CN or NO₂;
R¹ is a hydrogen atom, halogen atom of Cl, Br, or F, methyl group, alkyl group, aryl group, where one or more non-adjacent CH₂ groups of alkyl or aryl group may be replaced by oxygen atom, C═O, C═S, C═Se, C═NH, SiH₂, SO, SO₂, OS, or CONH and where one or more H atoms may be replaced by D, F, Cl, Br, I, CN or NO₂; or X¹ is an ester group; preferably said ester group is a carboxylic acid group;
R² is a hydrogen atom, halogen atom of Cl, Br, or F, methyl group, alkyl group, aryl group, where one or more non-adjacent CH₂ groups of alkyl or aryl group may be replaced by oxygen atom, C═O, C═S, C═Se, C═NH, SiH₂, SO, SO₂, OS, or CONH and where one or more H atoms may be replaced by D, F, Cl, Br, I, CN or NO₂; or X¹ is an ester group; preferably said ester group is a carboxylic acid group;

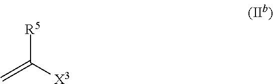

X³ is a non-substituted or substituted ester group, alkyl group, cyclo-alkyl group, aryl group or an alkoxy group, in case of X³ is a non-substituted or substituted ester group, said ester group is represented by following formula (II^{bs});

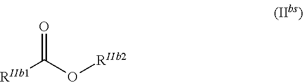

wherein R^{IIb1} is a single bond, a non-substituted or substituted alkylene chain having carbon atoms 1 to 5;
R^{IIb2} is a substituted or non-substituted alkyl group, cyclo group, cyclo-alkyl group, aryl group or an alkoxy group.

Furthermore preferably, R^{IIb1} of (II^{bs}) is a single bond, R^{IIb2} of (II^{bs}) is a substituted or non-substituted alkyl group, cyclo group, cyclo-alkyl group;
R^{IIb2} of (II^{bs}) can be selected from the groups indicated on table of page 44.

R⁵ is a hydrogen atom, halogen atom of Cl, Br, or F, methyl group, alkyl group, aryl group, alkoxy group, ester group, or a carboxylic acid group;

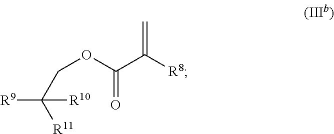

wherein R⁹ is hydrogen atom, a straight alkyl group having 1 to 25 carbon atoms or a (meth)acryl group represented by chemical formula (IV^{b})

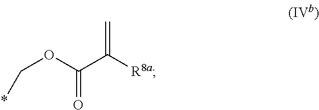

R¹⁰ is hydrogen atom, a straight alkyl group having 1 to 25 carbon atoms or a (meth)acryl group represented by chemical formula (V^{b})

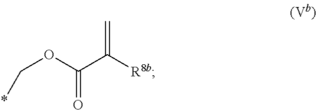

R¹¹ is hydrogen atom, a straight alkyl group having 1 to 25 carbon atoms or a (meth)acryl group represented by chemical formula (VI^{b})

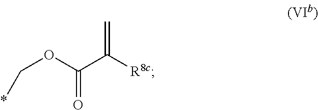

wherein R⁸, R^{8a}, R^{8b} and R^{8c} are, each independently or dependently of each other at each occurrence, H, CH₂CH₃ or CH₃;
wherein at least one of R⁹, R¹⁰ and R¹¹ is a (meth)acryl group.

9. A method for fabricating the composition of any one of preceding embodiments, comprising at least following steps,
(a) mixing at least a light emitting moiety, preferably said light emitting moiety comprises at least a 1^{st} semiconducting nanomaterial as a core, with another material to get a reaction mixture, preferably said another material is a solvent;
(b) forming an outer layer onto the outermost surface of the light emitting moiety in the reaction mixture by reacting at least an anion source represented by chemical formula (Va) or chemical formula (Vb) with a metal cation precursor in a reaction mixture;

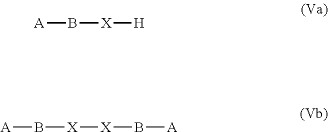

wherein
A is an organic group;
B is a connecting unit;
H is a hydrogen atom; and
X is an anchor group comprising an anion, capable to form a monolayer with the added metal cation derivable from the added metal cation precursor;
(c) cooling the reaction mixture from step (b),
wherein the reaction mixture in step (b) is kept at a temperature in the range from 80° C. to 200° C., preferably from 100 to 200° C. to form the outer layer in step (b),
(d) mixing a light emitting moiety obtained from step (c) with at least one reactive monomer or a mixture of two or more reactive monomers to from a composition.

10. The process of embodiment 9, wherein an injection of said anion source is carried out at the temperature in the range from 0° C. to 200° C., preferably in the range from 20° C. to 180° C. in step (a) or in step (b).

11. The process of embodiment 9 or 10, wherein step (b) is carried out in the range from 1 minute to 10 hours, preferably from 10 minutes to 5 hours, more preferably 20 minutes to 3 hours.

12. The process according to any one of embodiments 9 to 11, the ratio of the total molar amount of the cation precursor to the total molar amount of the semiconducting nanoparticle in step (b) is in the range from 20:1 to 200000:1, preferably from 100:1 to 60000:1, more preferably 110:1 to 58000:1, even more preferably 120:1 to 5000:1. Preferably, the ratio of the total mass amount of the cation precursor to the total mass amount of the semiconducting nanoparticle in step (b) is in the range from 1:1000 to 1:1, preferably from 1:500 to 1:2, more preferably 1:400 to 1:2. Preferably, the ratio of the total mass amount of the cation precursor to the total mass amount of the semiconducting nanoparticle in step (b) is in the range from 1:1000 to 1:1, preferably from 1:500 to 1:2, more preferably 1:400 to 1:2. Preferably, the molar ratio of the total amount of the anion source and the total amount of the cation precursor used in step (b) is in the range from 20:1 to 1:20, preferably in the range from 12:1 to 1:12, even more preferably 5:1 to 1:5.

13. The process according to any one of embodiments 9 to 12, wherein the anion source of formula (Vb) is used in step (b) together with a reducing agent to form the outer layer, preferably said reducing agent is represented by secondary phosphines.

14. The process according to any one of embodiments 9 to 13, wherein the molar ratio of the total amount of the anion source and the total amount of the cation precursor used in step (b) is in the range from 20:1 to 1:20, preferably in the range from 12:1 to 1:12, even more preferably 5:1 to 1:5.

15. A composition obtainable or obtained from the process according to any one of embodiments 9 to 14.

16. Formulation comprising at least a composition of any one of embodiments 1 to 8 and 15,
and at least one solvent, preferably the solvent is selected from one or more members of the group consisting of aromatic, halogenated and aliphatic hydrocarbon solvents, ethers, esters, ionic liquids, alcohols and water, more preferably selected from one or more members of the group consisting of toluene, xylene, tetrahydrofuran, chloroform, dichloromethane and heptane, hexane, purified water, ester acetates, ether acetates, ketones, etheric esters, preferably it is PGMEA, alcohols, preferably ethanol or isopropanol, sulfoxides, formamides, nitrides, ketones.

17. Use of the composition of any one of embodiments 1 to 8 or 15 or the formulation according to embodiment 16 in an electronic device, optical device, sensing device or in a biomedical device.

18. Method for forming a layer comprising:
S1) providing the composition of any one of embodiments 1 to 8 or 15 onto a substrate, preferably by ink-jetting;
S2) curing the composition, preferably said curing is a photo curing performed by photo irradiation, thermal curing or a combination of a photo curing and a thermal curing.

19. A layer obtained or obtainable from the method of embodiment 18.

20. A layer containing at least;
Xi) a light emitting moiety, preferably it is a semiconducting light emitting nanoparticle, comprising an outer layer containing a metal cation and a divalent anion; and
one or more types of organic moieties directly attached to the anion of the outer layer by covalent bond,
Xii) a polymer made from at least one reactive monomer or a mixture of two or more reactive monomers, preferably said monomer having one or more of functional groups, more preferably it is a(meth)acrylate monomer;
wherein said divalent anion of the outer layer is selected from Se²⁻, S²⁻, Te²⁻O²⁻ or a combination of any of these, preferably said metal cation of the outer layer is a monovalent, divalent, trivalent or tetravalent cation, more preferably said metal cation is a divalent cation selected from the group consisting of Zn²⁺, Ni²⁺, Co²⁺, Ca²⁺, Sr²⁺, Hg²⁺, Mg²⁺ and Pb²⁺, or a tetravalent cation selected from the group consisting of Ti⁴⁺, Ge⁴⁺, Si⁴⁺, Zr⁴⁺Hf⁴⁺, and Sn⁴⁺.

21. A color conversion device (100) comprising at least a 1^{st} pixel (161) partly or fully filled with the layer of embodiment 19 or 20 comprising at least a matrix material (120) containing a light emitting moiety (110), and a bank (150) comprising at least a polymer material, preferably the color conversion device (100) further contains a supporting medium (170).

22. An optical device (300) containing at least one functional medium (320, 420, 520) configured to modulate a light or configured to emit light, and the color conversion device (100) of embodiment 21.

### Technical Effects

The present invention provides one or more of following effects; realizing an optimized haze value of the cured layer (film), optimal haze value with improved EQE value of the cured layer (film), preferably obtaining optimal haze value with improved EQE value of the cured layer (film) without using scatting particle, improved thermal stability of an obtained layer (film), improved thermal stability of a light emitting moiety in a layer (film), improved dispersibility of a light emitting moiety in a composition, enabling a phase separation of light emitting moiety and matrix material after curing realizing an improved haze value of the cured film (cured composition), improved dispersibility of a light emitting moiety in an obtained layer, improved long term Quantum Yield (QY) stability of a light emitting moiety in the composition in a longer term storage with our without external light irradiation, improved long term External Quantum Efficiency (EQE) stability of a light emitting moiety in the composition in a longer term storage with our without external light irradiation, improved long term Quantum Yield (QY) stability of a light emitting moiety in the obtained layer (film) in a longer term storage with our without light external irradiation, improved long term External Quantum Efficiency (EQE) stability of a light emitting moiety in the obtained layer (film) in a longer term storage with our without external light irradiation, improved good compatibility of light emitting moiety with a matrix material in a composition and/or an obtained layer (film), and/or realizing easy handling of a composition containing a light emitting moiety and a matrix material, making composition suitable for inkjet printing.

The examples below provide descriptions of the present invention, as well as an in-detail description of their fabrication. However, the present invention is not necessary to be limited to the working examples.

### EXAMPLES

### Core Synthesis Example 1: Synthesis of Magic Sized Clusters (MSCs)

### Cluster Synthesis

In a 500 mL 4-neck flask, weight 4.65 g (15.9 mmol) of indium acetate and 13.25 g (58.0 mmol) of myristic acid. The flask is equipped with a reflux condenser, septa and a tap between the flask and the condenser.

Put under vacuum at 100° C. for 8 h 15 min to off-gas acetic acid under reduced pressure, and overnight at room T.

Day after, the solution heat again to 100° C. and evacuate for 1 hour and 45 min in those conditions.

Total evacuation time at 100° C. for 10 hours,

At pressure: 85 mTorr.

Fill the reaction flask with argon and add 100 mL of dry toluene. Heat the reaction to 110° C.

Inject the mixture of 2.33 mL (2.0 g) of PTMS and 50 mL (43.5 g) of toluene into the flask with indium myristate (In(Ma) at 110° C.

The formation of MSCs was monitored via UV-vis of timed aliquots taken from the reaction solution. There was a gradual improvement in the peak shape (red shift and sharpness).

When the improvement in the peak shape (red-shift and sharpness) is stopped the 2nd PTMS solution (1 ml (0.86 g) PTMS in 10.2 ml (8.77 g) Toluene) is added in portions of 2 mL to reach the optimal optical parameters. For example:
2 ml PTMS solution was added after 13 min
2 ml PTMS solution was added after 19 min
2 ml PTMS solution was added after 32 min

After 44 min cool the reaction with fan and store the flask itself under inert atmosphere.

### Results:

InP magic size clusters are formed with exciton at 387 nm.

The InP magic size clusters (MSCs) are cleaned with anhydrous acetonitrile (the ratio of crude:acetonitrile 18:13). The process is repeated with a mixture of anhydrous toluene and acetonitrile in ratio toluene:acetonitrile 1.5:1, 1.4:1, 1.75:1. This product is called “magic size clusters (MSCs)”.

### Core Synthesis Example 2: Core Synthesis

### Synthesis of InP Nanoparticles Having an Exciton Wavelength of 593 nm

A 50 mL, 14/20, four-neck round-bottom flask equipped with a reflux condenser is evacuated, and 10 mL of distilled squalane is injected into it. The apparatus is evacuated with stirring (pressure is loaded from 300 mtorr to 200 mTorr during 1 hour) and heated to 375° C. under argon. In a glove box a solution of MSCs with a concentration of 3.15×10⁻⁰⁴M is prepared in distilled squalane. 4 mL (1.26E-06 moles) of this solution is injected to the flask at 375° C., using a 16-gauge needle and 6 mL syringe; after 4 minutes the mantle is removed, and the flask is cooled to 200° C. by blowing air with a fan. The mantle is then brought back, and the flask is heated to 265° C.

At this point more MSCs are added, using the same solution that is initially injected; 20-gauge needle and 3 ml syringe are used, the addition is done at a rate of 0.7 ml/min at the given times (compared to the initial injection):
Minute 15-0.6 mL (1.89E-07 mol)
Minute 25-0.7 mL (2.21E-07 mol)
Minute 32-0.7 mL

### Results:

InP QDs are formed with exciton at 593 nm.

Shell synthesis example 1: ZnSe shell synthesis on InP cores, (trioctyl phosphine selenide (TOP-Se) as Se source)

In this example InP cores used are synthesized using the core synthesis described above (WO 2019/224134 A) and have core exciton CWL of 593 nm. The final core solution is cleaned with a mixture of anhydrous toluene and ethanol (ratio crude:toluene:ethanol: 1:2:8). The process is repeated with ratio crude:toluene:ethanol: 1:2:6. This solution will be called further “SSP InP cores”.

Post-synthesis core treatment: In glove box (GB), SSP InP cores (3.5×10⁻⁷ mol) are dissolved with 0.2 ml toluene and transferred into 50 ml round bottom flask with 4.8 ml pumped oleylamine (OLAm) and 0.085 g ZnCl₂. After short pumping at 50° C. to remove toluene, the flask is filled with argon and heated to 250° C. for 30 min. The solution is then cooled down to 180° C.

Shelling process: At 180° C., 2.6 mL of a 0.55M concentrated solution of Zn(Cl)₂ in OLAm and 1 amount (0.72 mL of 2M TOP-Se) of anion shell precursor are added to SSP InP cores after core treatment. After 30 min, the solution is heated to 200° C. After 30 min the solution is heated to 320° C., 3.2 mL of 0.4M Zn(Undecylenate)₂ is injected and the reaction kept at 320° C. for 3 hrs. After 3 hrs at 320° C. the reaction is terminated by cooling down the reaction mixture.

The resulting nanoparticles are cleaned with a mixture of anhydrous toluene and ethanol (ratio crude:toluene:ethanol: 3:4:8). The process is repeated. Then the nanoparticles are extracted with hexane.

Shell synthesis example 2: ZnSeS shell synthesis on InP cores, (trioctyl phosphine selenide (TOP-Se) as Se source, dodecanethiol (DDT) as S source)

The comparative example is similar to comparative example 1, but 0.9 mmol of TOP-Se is injected at 180° C.; and 0.56 mmol of DDT is injected at 320° C. 10 min after injection of Zn(Undecylenate)₂.

### Reference Example 1: ZnSe Outer Layer Synthesis on InP/ZnSe NPs in ODE, with 1-dodecaneselenol (DDSe) as Se Source

Outer layer synthesis: At room temperature, 8.3×10⁻⁸ mol of InP/ZnSe, described in comparative example 1, are dissolved with 0.2 ml toluene and transferred into 50 ml round bottom flask with 4 ml pumped 1-octadecene (ODE). After 30 min pumping at RT 1-dodecane selenol (0.2 mmol) is added and the flask is heated to 150° C. When temperature reached 150° C. Zn(Undecylenate)₂ (0.2 mmol) is added and the reaction kept at 150° C. for 1.5 hrs. After 1.5 hours at 150° C. the reaction is terminated by cooling down the reaction mixture.

The resulting nanoparticles are cleaned with a mixture of anhydrous toluene and ethanol (ratio crude:toluene:ethanol: 3:4:8). The process is repeated. Then the nanoparticles are extracted with hexane.

Table A compares the values of thermal, anti-radical, anti-peroxide stabilities for the described reference example and the comparative example 1.

### Reference Example 2: ZnS Outer Layer Synthesis on InP/ZnSe NPs in ODE, with 1-Dodecanethiol as S Source

The reference example 2 is similar to reference example 1, but 1-dodecanethiol is used as sulphur precursor.

### Reference Example 3: ZnSeS Outer Layer Synthesis on InP/ZnSe NPs in ODE, with 1-dodecaneselenol as Se Source and 1-dodecanethiol as Sulphur

The reference example 3 is similar to reference examples 1 and 2, however 1-dodecaneselenol and 1-dodecanethiol are added together at equal molar amounts keeping the amount of Se+S ions same as before.

### Reference Example 4: ZnSeS Outer Layer Synthesis on InP/ZnSe NPs in ODE, with 1-dodecaneselenol as Se Source and 3-phenylethane thiol as Sulphur Source

The reference example 4 differs from the reference example 3 by utilizing 3-phenylethane thiol instead of 1-dodecanethiol as sulphur source.

### Reference Example 5: ZnS Outer Layer Synthesis on InP/ZnSeS NPs in ODE, with 1-dodecanethiol as S Source

The reference example 5 is similar to reference example 2, but InP/ZnSeS particles are used. The InP/ZnSeS prepared as described in comp. ex. 2.

Table A compares the values of thermal, anti-radical, anti-peroxide stabilities for the described example and the comparative example 2.

### Reference Example 6: ZnS Outer Layer Synthesis on InP/ZnSe NPs in ODE, with Perfluorodecane thiol as S Source

The reference example is similar to reference example 2, but perfluorodecane thiol is used as sulphur precursor.

TABLE A

| | QY, % | | | |
|---|---|---|---|---|
| | Clean NPs | | | |
| | in toluene | After | After | After |
| | solution, | thermal | Benzoquinone | peroxide |
| Example | Abs 0.5-0.7 | stability test | test | test |
| Comparative | 51 | 29 | 13 | 26 |
| example 1 | | | | |
| Comparative | 43 | 25 | | |
| example 2 | | | | |
| Working | 53 | 50 | 40 | 51 |
| example 1 | | | | |
| Working | 47 | 44 | Not measured | Not |
| example 2 | | | | measured |
| Working | 47 | 42 | 47 | 40 |
| example 5 | | | | |

Thermal stability test—powder thermal test at 150° C. in air
Benzoquinone test—2.667% wt of p-benzoquinone added to clean NPs in toluene
Peroxide test—50% wt of tertbutylperoxybenzoate added to clean NP in toluene

### Reference Example 7: Experimental Proof of Surface and Crystal Binding of DDSe of QDs from Reference Example 1

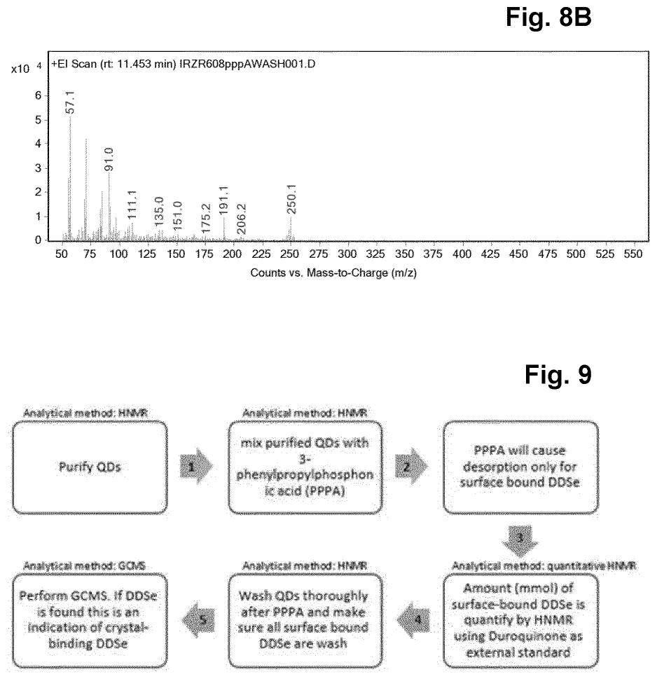

The general scheme mentioned in FIG. 9 (scheme1) describes a multi-step method that is established to characterize between surface and crystal bound ligands (covalently bound ligands), exemplified for dodecaneselenol (DDSe).

3-phenylpropylphosphonic acid (PPPA) is known for its stronger affinity to QDs surface compared to amines, thiols, selenols and carboxylic acids. Surface-bound ligands are desorbed from QDs surface and replaced by PPPA. On the other hand, crystal-bound ligands are integrated into the crystal lattice. Subsequently, their dissociation from QDs is impossible without destruction of the crystal. This process can also be used for experimental proof of crystal binding amine containing ligands, thiol containing ligands (e.g., mPEG thiols), other selenol containing ligands and carboxylic acid containing ligands of QDs.

Characterization of QDs from Reference Example 1:

FIG. 6: ¹H NMR spectra (in toluene d8) of QDs from reference example 1 before (a) and after (b) addition of PPPA

Addition of PPPA leads to desorption of DDSe from QDs surface.

Amount (in mmol) of detached DDSe (surface-bound) is calculated by quantitative ¹H NMR using Duroquinone as external standard and is equal to 0.00135 mmol. Meaning, Only 1.8% mol from total amount of DDSe that is inserted to reaction produced surface bound DDSe.

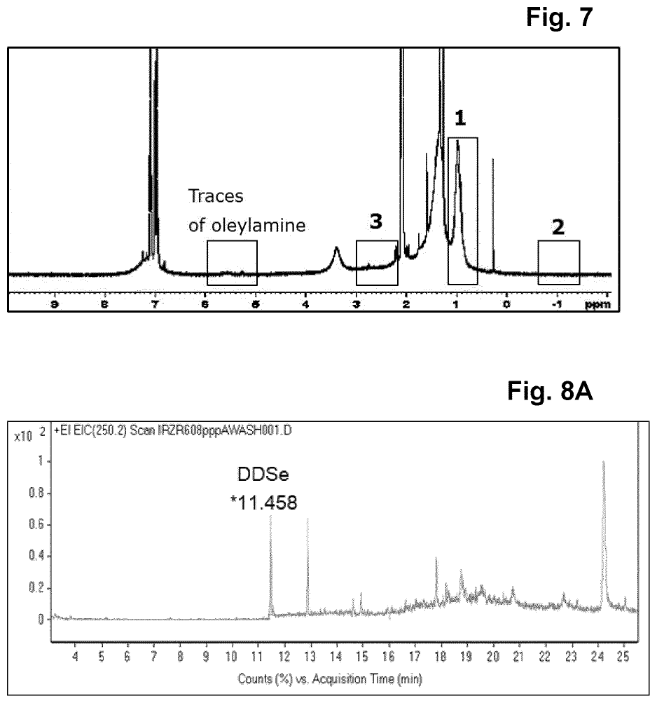

FIG. 7: ¹H NMR spectrum (in toluene d8) of QDs after treating with PPPA and washing with ethanol

¹H NMR indicates that surface-bound DDSe is completely removed from the surface of the QDs (signal #2 (Se—H) and signal #3 (CH₂—Se) disappeared). However, Signal #1 (CH₃ of DDSe) still exist. This is an indication of presence of a second population of DDSe which is not surface bound.

QDs after removing all surface bound DDSe are analyzed in GCMS. For this purpose, proper derivatization with HCl and methanol is performed.

This treatment leads to complete decomposition and dissolution of QDs.

FIG. 8A, 8B: GCMS spectrum for QDs after treating with PPPA and washing. MS spectrum of peak at retention time of 11.458.

The sample for GCMS is prepared as described in embodiments. GCMS confirms presence of DDSe. This indicates crystal binding of DDSe.

Main conclusion: QDs from reference example 1 contain surface- as well as crystal-bound DDSe.

### Reference Example 8: ZnS Outer Layer Synthesis on InP Based Red Quantum Dots in PGMEA, with poly(ethylene glycol) methyl ether thiol Mn 800 (mPEG800-SH) as S Source

Weight 183.5 mg (1 mmol) of Zn(OAc)₂ in the 50 mL-round bottom 4-neck reaction flask, put under vacuum for 40 minutes, put under argon, introduce to the glove box, add 6 mL of PGMEA and 0.61 mL of InP based red quantum materials (QMs).
Observation—red suspension.
Put under vacuum at room T, 20 min.
Put under Ar.
Add 2 mL of PGMEA.
Heated (in 8 min) to 144 C (reflux, cool the condenser with the water flow).

At 144 C inject 1.15 mL of the 0.43M mPEG-SH solution in PGMEA—t=0
Stay 65 min at 144° C.
inject 1.15 mL of the 0.43M mPEG-SH solution in PGMEA.
Stay 70 min at 144° C. End. In total—2 hrs 15 min at 144° C.

The resulting QDs are cleaned with anhydrous hexane (the ratio of crude:hexane 1:1). The process is repeated with a mixture of anhydrous PGMEA:hexane 1:1. Then the QDs are extracted with toluene.

TABLE B

| | QY, % | | |
|---|---|---|---|
| | | In non-polar | |
| | Clean in | matrix, after 30 | In polar matrix I, |
| | toluene | min at 180 C. under | after 30 min at |
| Example | solution | air | 180 C. under air |
| InP based red | 67 | 40 | insoluble |
| QDs w/o crystal | | | |
| bound mPEG800- | | | |
| SH | | | |
| Working example 8 | 68 | 62 | 62 |

Table B compares the values of thermal stability for the described reference example 8 and for the used first semiconducting material (InP based red quantum materials).

### Reference Example 9: ZnS Outer Layer Synthesis on InP Based Red Quantum Dots in PGMEA, with poly(ethylene glycol) methyl ether thiol Mn 800 (mPEG800-SH) as S Source

1.28 g of zinc acetate (Zn(OAc)₂) are weighted into 250 ml round bottom flask and degassed for 25 min at 200 mTorr while stirring. Put under Ar atmosphere. Inserted into the glove box.

56 ml PGMEA and toluene solution of 2.1 gr of InP based red quantum materials is added. The mixture is mounted on a Schlenk line. Put under Ar.

Distillation set-up is mounted and toluene is distilled out.

The flask is heated to reflux and 7.7 ml of 0.4M mPEG800-SH solution in PGMEA is injected.

After 65 min another portion of 7.7 ml of 0.4M mPEG800-SH solution in PGMEA is injected.

The flask is cooled to RT after additional 70 min at reflux (total reaction time 2 h and 15 min).

The resulting QDs are cleaned as follows: solids are removed by centrifugation; QDs are precipitated with anhydrous hexane (the ratio of crude:hexane 1:1); the process is repeated with a mixture of anhydrous PGMEA:hexane 1:1, then twice with anhydrous toluene:hexane 2:3.

TABLE C

| | QY, % | |
|---|---|---|
| | Clean in | |
| | toluene | In polar matrix II, after 30 min at 180 C. |
| Example | solution | under argon |
| InP based red | 68 | 28 |
| QDs with surface | | |
| bound mPEG800- | | |
| SH | | |
| Working example 9 | 68 | 46 |

Table C compares the values of thermal stability for the described Working example 9 with reference material, which is prepared similarly to Working example 9, but without Zn(OAc)₂.

### Reference Example 10: ZnS Outer Layer Synthesis on InP Based Green Quantum Material Having Core-Shell Structure in diisoptopylbenzene, with poly(ethylene glycol) methyl ether thiol Mn 350 (mPEG350-SH) as S Source

0.215 g of Zn(OAc)₂ is weighted outside GB into 50 ml round bottom flask, the flask is introduced to GB. 8 ml of diisopropylbenzene (DIPB) and then toluene solution of 270 mg of InP based green quantum dots are added.

The mixture is mounted on a Schlenk line and the toluene is removed under reduced pressure. The flask is filled with Ar. The flask is heated to 160° C. and 1.3 ml of 0.9M mPEG(350)-SH solution in diisopropylbenzene is injected. After 90 min at 160° C. the reaction cooled to ambient temperature. QDs precipitated upon cooling below 50 C. Toluene (6 mL) is added to dissolve the quantum dots.

The resulting QDs are cleaned as follows: solids are removed by centrifugation; QDs are precipitated with anhydrous heptane (the ratio of (crude+toluene):heptane 1:1), the process is repeated with a mixture of anhydrous PGMEA:heptane 1:2, then with anhydrous toluene:heptane 1:1.

### Working Examples

IBOA=isobornyl acrylate
DPGDA=di-propyleneglycol di-acrylate
LA=lauryl acrylate
HDDA=1,6-Hexanediol diacrylate
TMPTA=Trimethylolpropane triacrylate

### Working Example 1

QD surface passivation and purification is performed under inert atmosphere.

In a separate vial, 0.242 g of mPEG350-SH and 2 ml of PGMEA is mixed to give mPEG350-SH stock solution.

In a reaction flask, 1.09 g of red QD (having InP core, ZnSe/ZnS double shell layers) with oleic acid as ligand dispersed in heptane, 31 mg of Zn(OAc)2 and 14 g of propylene glycol methyl ether acetate (PGMEA) are mixed. Heptane is removed under reduced pressure. The resulting mixture is headed to reflux.

Half of the amount of the mPEG350-SH stock solution is injected to the reaction flask, which continued to be heated to reflux for 1 h.

The second half of the mPEG350-SH stock solution is injected into the reaction flask, which continued to be heated to reflux for another 1 h.

The reaction is cooled to room temperature, transferred into appropriate centrifuge bottle and centrifuged at 2795G for 5 minutes to remove any solids. The red supernatant is transferred to an appropriate centrifuge bottle. For every volume of the reaction mixture one volume of heptane is added (e.g., for 15 mL of the reaction mixture 15 mL of heptane is added). Centrifuged at 2795G for 5 minutes, the supernatant is discharged.

The precipitated QDs are redispersed in 16 mL of toluene. The dispersion is centrifugated at 2795G for 5 minutes to discard residual solids.

The QD dispersion is transferred to a brown glass bottle and stored under inert atmosphere.

### Working Example 2

QD surface passivation and purification is performed under inert atmosphere.

In a separate vial, 0.364 g of mPEG350-SH and 2 ml of PGMEA is mixed to give mPEG350-SH stock solution.

In a reaction flask, 1.09 g of red QD (having InP core, ZnSe/ZnS double shell layers) with oleic acid as ligand dispersed in heptane, 191 mg of Zn(OAc)2 and 14 g of propylene glycol methyl ether acetate (PGMEA) are mixed. Heptane is removed under reduced pressure. The resulting mixture is headed to reflux.

Half of the amount of the mPEG350-SH stock solution is injected to the reaction flask, which continued to be heated to reflux for 1 h.

The second half of the mPEG350-SH stock solution is injected into the reaction flask, which continued to be heated to reflux for another 1 h.

The reaction is cooled to room temperature, transferred into appropriate centrifuge bottle and centrifuged at 2795G for 5 minutes to remove any solids. The red supernatant is transferred to an appropriate centrifuge bottle. For every volume of the reaction mixture 2.65 volumes of heptane is added (e.g., for 18 mL of the reaction mixture 47.7 mL of heptane is added). Centrifuged at 2795G for 5 minutes, the supernatant is discharged. The precipitated QDs are redispersed in 6 mL of toluene. Then 6 mL of heptane is added. Centrifuged at 2795G for 5 minutes, the supernatant is discharged. The precipitated QDs are redispersed in 6 mL of toluene. The dispersion is centrifugated at 2795G for 5 minutes to discard residual solids. The QD dispersion is transferred to a brown glass bottle and stored under inert atmosphere.

### Working Example 3

QD surface passivation and purification is performed under inert atmosphere.

In a separate vial, 1.216 g of mPEG350-SH and 6 ml of PGMEA is mixed to give mPEG350-SH stock solution.

In a reaction flask, 3 g of red QD (having InP core, ZnSe/ZnS double shell layers) with oleic acid as ligand dispersed in heptane, 558 mg of Zn(OAc)2 and 39 g of propylene glycol methyl ether acetate (PGMEA) are mixed.

Heptane is removed under reduced pressure. The resulting mixture is headed to reflux.

Half of the amount of the mPEG350-SH stock solution is injected to the reaction flask, which continued to be heated to reflux for 1 h.

The second half of the mPEG350-SH stock solution is injected into the reaction flask, which continued to be heated to reflux for another 1 h.

The reaction is cooled to room temperature, transferred into appropriate centrifuge bottle and centrifuged at 2795G for 5 minutes to remove any solids. The red supernatant is transferred to an appropriate centrifuge bottle. For every volume of the reaction mixture 0.75 volumes of heptane is added (e.g., for 40 mL of the reaction mixture 30 mL of heptane is added). Centrifuged at 2795G for 5 minutes, the supernatant is discharged. The precipitated QDs are redispersed in 32 mL of toluene. Then 16 mL of heptane is added. Centrifuged at 2795G for 5 minutes, the supernatant is discharged. The precipitated QDs are redispersed in 8 mL of toluene. The dispersion is centrifugated at 2795G for 5 minutes to discard residual solids. The QD dispersion is transferred to a brown glass bottle and stored under inert atmosphere.

### Working Example 4

QDs from Working Example 1 (0.2 g) dispersed in toluene are introduced in a glass vial. The monomers Isobornyl acrylate (IBOA) (263.3 mg) and trimethylopropane triacrylate (TMPTA) (29.3 mg) are added. Then, the photoinitiator Omnirad819 (5 mg) and the antioxidant IRGANOX 1010 (2.5 mg) are added. The formulation is shook for 10 minutes and volatiles are evaporated on rotary evaporator under vacuum at 25° C. Remaining volatiles are removed under vacuum of 60 mTorr on a Schlenk line.

### Working Example 5

QDs from working Example 2 (0.2 g) dispersed in toluene are introduced in a glass vial. The monomers IBOA (117 mg), polyethylene glycol methacrylate (MW 360) (117 mg) and triethylene glycol dimethacrylate (58.5 mg) are added. Then, the photoinitiator Omnirad819 (50 mg) and the antioxidant IRGANOX 1010 (25 mg) are added. The formulation is shook for 10 minutes and volatiles are evaporated on rotary evaporator under vacuum at 25° C. Remaining volatiles are removed under vacuum of 60 mTorr on a Schlenk line.

### Working Example 6

QDs from Working Example 3 (0.2 g) dispersed in toluene are introduced in a glass vial. The monomers IBOA (147 mg), triethylene glycol dimethacrylate (147 mg) are added. Then, the photoinitiator Omnirad819 (5 mg) and the antioxidant IRGANOX 1010 (2.5 mg) are added. The formulation is shook for 10 minutes and volatiles are evaporated on rotary evaporator under vacuum at 25° C. Remaining volatiles are removed under vacuum of 60 mTorr on a Schlenk line.

### Working Example 7

QDs from Working Example 1 (0.2 g) dispersed in toluene are introduced in a glass vial. The monomers IBOA (234 mg), triethylene glycol dimethacrylate (0.058 mg) are added. Then, the photoinitiator Omnirad819 (5 mg) and the antioxidant IRGANOX 1010 (2.5 mg) are added. The formulation is shook for 10 minutes and volatiles are evaporated on rotary evaporator under vacuum at 25° C. Remaining volatiles are removed under vacuum of 60 mTorr on a Schlenk line.

### Working Example 8

QDs from Working Example 3 (0.2 g) dispersed in toluene are introduced in a glass vial. The monomers polyethylene glycol methacrylate (MW 360) (468 mg), ethylene glycol dimethacrylate (117 mg) are added. Then, the photoinitiator Omnirad819 (5 mg) and the antioxidant IRGANOX 1010 (2.5 mg) are added. The formulation is shook for 10 minutes and volatiles are evaporated on rotary evaporator under vacuum at 25° C. Remaining volatiles are removed under vacuum of 60 mTorr on a Schlenk line.

### Working Example 9

QDs from Working Example 3 (0.2 g) dispersed in toluene are introduced with mPEG-SH (60 mg) in a glass vial. The monomers IBOA (472 mg) and TMPTA (53 mg) are added. Then, the photoinitiator Omnirad819 (5 mg) and the antioxidant IRGANOX 1010 (2.5 mg) are added. The formulation is shook for 10 minutes and volatiles are evaporated on rotary evaporator under vacuum at 25° C. Remaining volatiles are removed under vacuum of 60 mTorr on a Schlenk line.

### Working Example 10

QDs from Working Example 2 (0.2 g) dispersed in toluene are introduced with mPEG-SH (60 mg) in a glass vial. The monomers LA (420 mg) and HDDA (105 mg) are added. Then, the photoinitiator Omnirad819 (5 mg) and the antioxidant IRGANOX 1010 (2.5 mg) are added. The formulation is shook for 10 minutes and volatiles are evaporated on rotary evaporator under vacuum at 25° C. Remaining volatiles are removed under vacuum of 60 mTorr on a Schlenk line.

### Working Example 11

QDs from Working Example 3 (0.4 g) dispersed in toluene are introduced in a glass vial. The monomers IBOA (351 mg) and dipropylene glycol diacrylate (DPGDA) (234 mg) are added. Then, the photoinitiator Omnirad819 (10 mg) and the antioxidant IRGANOX 1010 (5 mg) are added. The formulation is shaken for 10 minutes and volatiles are evaporated on rotary evaporator under vacuum at 25° C. Remaining volatiles are removed under vacuum of 60 mTorr on a Schlenk line.

### Working Example 12

QDs from Working Example 3 (0.4 g) dispersed in toluene and mPEG-SH (60 mg) are introduced in a glass vial. The resulting mixture is heated to 40 deg C. for 80 min. The monomers IBOA (315 mg) and dipropylene glycol diacrylate (DPGDA) (210 mg) are added. Then, the photoinitiator Omnirad819 (10 mg) and the antioxidant IRGANOX 1010 (5 mg) are added. The formulation is shook for 10 minutes and volatiles are evaporated on rotary evaporator under vacuum at 25° C. Remaining volatiles are removed under vacuum of 60 mTorr on a Schlenk line.

### Working Example 13

QDs from Working Example 3 (0.4 g) dispersed in toluene and octadecane thiol (48 mg) are introduced in a glass vial. The suspension is heated to 80 deg C. for 2 hours. The monomers LA (322 mg) and HAAD (215 mg) are added. Then, the photoinitiator Omnirad819 (10 mg) and the antioxidant IRGANOX 1010 (5 mg) are added. The formulation is shaken for 10 minutes and volatiles are evaporated on rotary evaporator under vacuum at 25° C. Remaining volatiles are removed under vacuum of 60 mTorr on a Schlenk line.

### Working Example 14

QDs from Working Example 3 (1.0 g) dispersed in toluene and mPEG350-SH (150 mg) are introduced in a glass vial. The suspension is heated to 40 deg C. for 2 hours. The monomers IBOA (1.181 g) and TMPTA (131 mg) are added. Then, the photoinitiator Omnirad819 (25 mg) and the antioxidant IRGANOX 1010 (12.5 mg) are added. The formulation is shaken for 10 minutes and volatiles are evaporated on rotary evaporator under vacuum at 25° C. Remaining volatiles are removed under vacuum of 60 mTorr on a Schlenk line.

### Comparative Example 1: (Compare to Working Example 4)

A solvent borne ink is formed with native QDs.

0.2 g red QDs (having InP core, ZnSe/ZnS double shell layers) with oleic acid as ligand dispersed in heptane, are introduced in a glass vial. The monomers IBOA (263.3 mg), and TMPTA (29.3 mg) are added. Then, the photoinitiator Omnirad819 (50 mg) and the antioxidant1010 (25 mg) are added. The formulation is shook for 10 minutes and volatiles are evaporated on rotary evaporator under vacuum at 25° C. Remaining volatiles are removed under vacuum of 60 mTorr on a Schlenk line.

### Comparative Example 2: (Compare to Working Example 4)

A solvent borne ink is formed with native QDs and the additive mPEG-SH. 0.2 g red QDs (having InP core, ZnSe/ZnS double shell layers) with oleic acid as ligand dispersed in heptane, and 51.9 mg of mPEG-SH (MW 350) are introduced in a glass vial. The monomers IBOA (263.3 mg), and TMPTA (29.3 mg) are added. Then, the photoinitiator Omnirad819 (50 mg) and the antioxidant1010 (25 mg) are added. The formulation is shook for 10 minutes and volatiles are evaporated on rotary evaporator under vacuum at 25° C. Remaining volatiles are removed under vacuum of 60 mTorr on a Schlenk line.

### Comparative Example 3: (Compare to Working Example 11 and 12)

A solvent borne ink is formed with native QDs and the additive mPEG-SH. 0.16 g red QDs (having InP core, ZnSe/ZnS double shell layers) with oleic acid as ligand dispersed in heptane, and 40 mg of mPEG-SH (MW 350) are introduced in a glass vial. The monomers IBOA (116 mg), and DPGDA (78 mg) are added. Then, the photoinitiator Omnirad819 (40 mg) and the antioxidant IRGANOX 1010 (20 mg) are added. The formulation is shook for 10 minutes and volatiles are evaporated on rotary evaporator under vacuum at 25° C. Remaining volatiles are removed under vacuum of 60 mTorr on a Schlenk line

### Films Formation:

Films are formed by filling glass sandwiches cells (gap around 10 μm) with inks described in the previous examples. The films are cured by UV light (300 mW/cm² for 10 seconds). The cells are then opened, resulting in an open films deposited in one of the cell glass.

The open films are heated (thermal annealing) at 180° C. for 30 minutes under inert atmosphere. After the thermal annealing, the films are stored in a humidity controlled chamber under 25° C. and relative humidity (RH) of 45%.

The QY and EQE are measured 1 h after the thermal annealing and after 3 or 5 days of storage, as indicated in the tables 1 to 4 below.

EQE=Photons [Emission light]/Photons [Excitation light measured without sample in place];

According to the present invention, said EQE is measured by the following EQE measurement process at room temperature which is based on using an integrating sphere, equipped with a 450 nm excitation light source coupled in via an optical fiber, and a spectrometer (Compass X, BWTEK), and which consists of a first measurement using air as the reference to detect the incident photons of the excitation light and a second measurement with the sample or test cell placed in front of the integrating sphere in between the opening of the integrating sphere and the exit of the optical fiber to detect the photons incident from the excitation light source transmitted through the sample and the photos emitted from the sample or test cell, whereas for both cases photons exiting the integrating sphere are counted by the spectrometer and EQE and BL calculation is done with the following equations and the number of photons of the excitation light and emission light is calculated by integration over the following wavelength ranges;

EQE=Photons [Emission light]/Photons [Excitation light measured without sample in place];

BL=Photons [−Excitation light measured with sample in place]/Photons [Excitation light measured without sample in place];
Emission light if green light emitting moieties are used: 490 nm-600 nm,
Emission light if red light emitting moieties are used: 580 nm-780 nm
Excitation light: 390 nm-490 nm.

TABLE 1

| | QY | | |
|---|---|---|---|
| Film prepared with | After thermal | After 3 days of | Relative |
| ink: | annealing | storage | Decrease |
| Working Example 4 | 69.8% | 54.2% | −22.4% |
| Working Example 4 | (no thermal | 54.9% | −20.7% |
| (no thermal | annealing) | | |
| annealing) | 69.2% | | |
| Comparative | 62.9% | 34.1% | −45.7% |
| example 1 | | | |
| Comparative | 59.5% | 29.8% | −49.9% |
| example 2 | | | |

TABLE 2

| | EQE | | |
|---|---|---|---|
| Film prepared with | After thermal | After 3 days of | Relative |
| ink: | annealing | storage | Decrease |
| Working Example 4 | 26.0% | 21.2% | −18.65% |
| Working Example 4 | (no thermal | 20.7% | −14.11% |
| (no thermal | annealing) | | |
| annealing) | 24.1% | | |
| Comparative | 24.9% | 16.2% | −35.01% |
| example 1 | | | |
| Comparative | 19.9% | 11.5% | −42.46% |
| example 2 | | | |

TABLE 3

| | QY | | |
|---|---|---|---|
| Film prepared with | After thermal | After 3 days of | Relative |
| ink: | annealing | storage | Decrease |
| Working Example 11 | 86.5% | 80.6% | −6.8% |
| Working Example 12 | 90.1% | 83.3% | −7.5% |
| Comparative | 91.6% | 41.8% | −54.4% |
| example 3 | | | |
| Working Example 13 | 93.6% | 87.3% | −6.8% |
| Working Example 14 | 91.8% | 82.5% | −10.1% |

TABLE 4

| | EQE | | |
|---|---|---|---|
| Film prepared with | After thermal | After 3 days of | |
| ink: | annealing | storage | Decrease |
| Working Example 11 | 30.4% | 29.2% | −3.9% |
| Working Example 12 | 32.0% | 30.8% | −3.8% |
| Comparative | 32.3% | 18.0% | −44.4% |
| example 3 | | | |
| Working Example 13 | 34.8% | 33.6% | −3.5% |
| Working Example 14 | 33.2% | 31.5% | −5.3% |

### Working Example 15

Red QD ink containing Red QDs (having InP core, ZnSe/ZnS double shell layers) having two different types of ligands made from mPEG-(SH) and oleic acid, is prepared by mixing the materials mentioned below in table 5.

TABLE 5
Red QD ink composition

| | | |
|---|---|---|
| Red QDs | 40.00 | wt % |
| 1-Octadecanethiol | 4.80 | wt % |
| LA | 32.22 | wt % |
| HDDA | 21.48 | wt % |
| Omnirad819 | 1.00 | wt % |
| Irganox1010 | 0.50 | wt % |
| Total | 100.00 | wt % |

### Working Example 16

QD films obtained by working example 15 is stored under atmosphere at 25° C., 45% RH. EQE of QD films is monitored until 5 days.

### Results

The red QD inks of working example 15 shows excellent dispersibility.

QD film that films thickness 10 μm is obtained by working example 16.

EQE keeps over 97% after 5 days under atmosphere condition.

1.-15. (canceled)

16. A composition comprising at least;
i) a light emitting moiety comprising an outer layer containing a metal cation and a divalent anion; and
one or more types of organic moieties directly attached to the anion of the outer layer by covalent bond,
ii) at least one reactive monomer or a mixture of two or more reactive monomers;
wherein said divalent anion of the outer layer is selected from Se²⁻, S²⁻, Te²⁻O²⁻ or a combination of a divalent, trivalent or tetravalent cation.

17. The composition of claim 16, wherein the organic moiety is represented by following chemical formula (I); 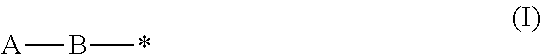
wherein
A is an organic group comprising hydrocarbyl, heteroaromatic group, including aryl, alkaryl, alkyl or aralkyl, alkylamine, fluoroaryl, fluoroalkaryl, fluoroalkyl, fluoroaralkyl, heteroaromatic group, including fluoroaryl, fluoroalkaryl, fluoroalkyl or fluoroaralkyl;
B is a connecting unit, wherein B is **-(U)ₒ-(Y)ₘ-(CR^{IIa}R^{IIb})ₙ wherein “**” represents the connecting point to “A;” and
“*” represents the connecting point to the anion in the outer layer.

18. The composition of claim 16, wherein the organic moiety is represented by following chemical formula (II), (III) or (III′); 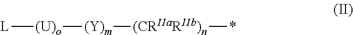
wherein
L is an organic group comprising hydrocarbyl, heteroaromatic group, including aryl, alkaryl, alkyl or aralkyl, alkylamine, fluoroaryl, fluoroalkaryl, fluoroalkyl, fluoroaralkyl, heteroaromatic group, including fluoroaryl, fluoroalkaryl, fluoroalkyl or fluoroaralkyl;
U is O, CH₂ or C═O;
Y is O, CH₂ or C═O;
R^{a} and R^{b} are, each independently each other, at each occurrence, selected from hydrogen atom, a hydroxy group, a straight alkyl group having 1 to 10 carbon atoms, a branched alkyl group having 3 to 10 carbon atoms; preferably a hydrogen atom, a hydroxy group, a straight alkyl group having 1 to 5 carbon atoms, a branched alkyl group having 3 to 5 carbon atoms; preferably R^{IIa} and R^{IIb} are hydrogen atom;
n is an integer 1 or more;
m is 0 or an integer 1 or more;
o is 0 or an integer 1 or more;
“*” represents the connecting point to the anion in the outer layer; 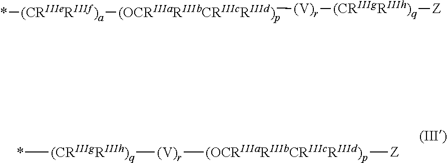
wherein
R^{IIIa}, R^{IIIb}, R^{IIIc}, R^{IIId}, R^{IIIe}, R^{IIIf}, R^{IIIg} and R^{IIIh} are, each independently each other, at each occurrence, selected from hydrogen atom, a hydroxy group, a straight alkyl group having 1 to 10 carbon atoms, a branched alkyl group having 3 to 10 carbon atoms;
preferably a hydrogen atom, a hydroxy group, a straight alkyl group having 1 to 5 carbon atoms, a branched alkyl group having 3 to 5 carbon atoms; preferably R^{IIIg} and R^{IIIh} are hydrogen atom, preferably R^{IIIe} and R^{IIIf} are hydrogen atom; V is O, CH₂ or C═O;
Z is a hydrogen atom or an organic group, a straight alkyl group having 1 to 25 carbon atoms, a branched alkyl group having 3 to 25 carbon atoms, —COOH, —SH, or —NH₂, alkylamine, fluoroaryl, fluoroalkaryl, fluoroalkyl, fluoroaralkyl, heteroaromatic group, including fluoroaryl, fluoroalkaryl, fluoroalkyl or fluoroaralkyl, a straight alkyl group having 1 to 25 carbon atoms, a branched alkyl group having 3 to 25 carbon atoms, a straight alkyl group having 1-15 carbon atoms, a branched alkyl group having 3-15 carbon atoms, even more preferably it is a hydrogen atom, or a straight alkyl group having 1-10 carbon atoms;
a is 0 or an integer 1 or more;
p is 0 or an integer 1 or more;
q is 0 or an integer 1 or more;
r is 0 or an integer 1;
“*” represents the connecting point to the anion in the outer layer.

19. The composition of claim 16, wherein the organic moiety is represented by following chemical formula (IV): 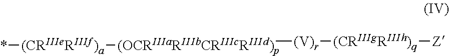
wherein
R^{IIIa}, R^{IIIb}, R^{IIIc}, R^{IIId}, R^{IIIe}, R^{IIIf}, R^{IIIg} and R^{IIIh} are, each independently each other, at each occurrence, selected from hydrogen atom, a hydroxy group, a straight alkyl group having 1 to 10 carbon atoms, a branched alkyl group having 3 to 10 carbon atoms;
a is 0 or an integer 1 or more;
p is 0 or an integer 1 or more;
q is 0 or an integer 1 or more;
V is O, CH₂ or C═O;
Z′ is a hydrogen atom a straight alkyl group having 1 to 25 carbon atoms, a branched alkyl group having 3 to 25 carbon atoms, alkylamine, fluoroaryl, fluoroalkaryl, fluoroalkyl, fluoroaralkyl, heteroaromatic group, including fluoroaryl, fluoroalkaryl, fluoroalkyl or fluoroaralkyl;
r is 0 or an integer 1;
“*” represents the connecting point to the anion in the outer layer.

20. The composition of claim 16, wherein the organic moiety is covalently bound to the anion in the outer layer of an inorganic lattice.

21. The composition of claim 16, wherein metal cation is a transition metal of group 12 or group 14.

22. The composition of claim 16, wherein said reactive monomer is a (meth)acrylate monomer selected from a mono-(meth)acrylate monomer, a di-(meth)acrylate monomer and/or a tri-(meth)acrylate monomer.

23. The composition of claim 22, said di-(meth)acrylate monomer is represented by following chemical formula (I^{b}), said mono-acrylate monomer is represented by following chemical formula (II^{b}) and/or said tri-(meth)acrylate monomer is represented by following chemical formula (III^{b}); 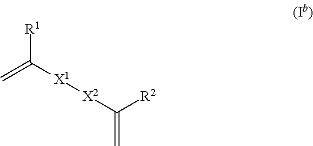
wherein
X¹ is a non-substituted or substituted ester group, alkyl group or aryl group, where one or more non-adjacent CH₂ groups of ester, alkyl or aryl group may be replaced by oxygen atom, C═O, C═S, C═Se, C═NH, SiH₂, SO, SO₂, OS, or CONH and where one or more H atoms may be replaced by D, F, Cl, Br, I, CN or NO₂; preferably said ester group is represented by following formula (I^{bs1}); 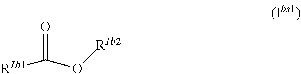
wherein R^{Ib1} is a single bond, a non-substituted or substituted alkylene chain having carbon atoms 1 to 5;
R^{Ib2} is a single bond, a non-substituted or substituted straight alkylene chain having carbon atoms 1 to 5, a non-substituted or substituted branched alkylene chain having carbon atoms 3 to 7, where one or more non-adjacent CH₂ groups may be replaced by oxygen atom, C═O, C═S, C═Se, C═NH, SiH₂, SO, SO₂, OS, or CONH and where one or more H atoms may be replaced by D, F, Cl, Br, I, CN or NO₂;
X² is a non-substituted or substituted non-substituted or substituted ester group, alkyl group or aryl group, where one or more non-adjacent CH₂ groups of ester, alkyl or aryl group may be replaced by oxygen atom, C═O, C═S, C═Se, C═NH, SiH₂, SO, SO₂, OS, or CONH and where one or more H atoms may be replaced by D, F, Cl, Br, I, CN or NO₂;
preferably said ester group is represented by following formula (I^{bs2}); 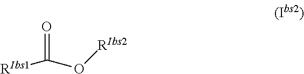
wherein R^{Ibs1} is a single bond, a non-substituted or substituted alkylene chain having carbon atoms 1 to 5;
R^{Ibs2} is a single bond, a non-substituted or substituted straight alkylene chain having carbon atoms 1 to 5, a non-substituted or substituted branched alkylene chain having carbon atoms 3 to 7, where one or more non-adjacent CH₂ groups may be replaced by oxygen atom, C═O, C═S, C═Se, C═NH, SiH₂, SO, SO₂, OS, or CONH and where one or more H atoms may be replaced by D, F, Cl, Br, I, CN or NO₂;
R¹ is a hydrogen atom, halogen atom of Cl, Br, or F, methyl group, alkyl group, aryl group, where one or more non-adjacent CH₂ groups of alkyl or aryl group may be replaced by oxygen atom, C═O, C═S, C═Se, C═NH, SiH₂, SO, SO₂, OS, or CONH and where one or more H atoms may be replaced by D, F, Cl, Br, I, CN or NO₂; or X¹ is an ester group;
R² is a hydrogen atom, halogen atom of Cl, Br, or F, methyl group, alkyl group, aryl group, where one or more non-adjacent CH₂ groups of alkyl or aryl group may be replaced by oxygen atom, C═O, C═S, C═Se, C═NH, SiH₂, SO, SO₂, OS, or CONH and where one or more H atoms may be replaced by D, F, Cl, Br, I, CN or NO₂; or X¹ is an ester group; 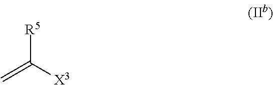
X³ is a non-substituted or substituted ester group, alkyl group, cyclo-alkyl group, aryl group or an alkoxy group, in case of X³ is a non-substituted or substituted ester group, said ester group is represented by following formula (II^{bs}); 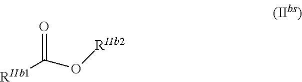
wherein R^{IIb1} is a single bond, a non-substituted or substituted alkylene chain having carbon atoms 1 to 5;
R^{IIb2} is a substituted or non-substituted alkyl group, cyclo group, cyclo-alkyl group, aryl group or an alkoxy group.
R⁵ is a hydrogen atom, halogen atom of Cl, Br, or F, methyl group, alkyl group, aryl group, alkoxy group, ester group, or a carboxylic acid group; 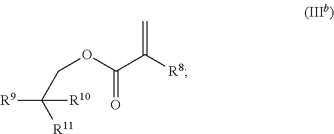
wherein R⁹ is hydrogen atom, a straight alkyl group having 1 to 25 carbon atoms or a (meth)acryl group represented by chemical formula (IV^{b}) 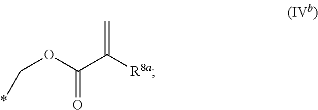
R¹⁰ is hydrogen atom, a straight alkyl group having 1 to 25 carbon atoms or a (meth)acryl group represented by chemical formula (V^{b}) 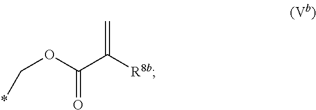
R¹¹ is hydrogen atom, a straight alkyl group having 1 to 25 carbon atoms or a (meth)acryl group represented by chemical formula (VI^{b}) 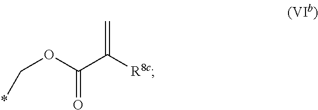
wherein R⁸, R^{8a}, R^{8b} and R^{8c} are, each independently or dependently of each other at each occurrence, H, CH₂CH₃ or CH₃;
wherein at least one of R⁹, R¹⁰ and R¹¹ is a (meth)acryl group.

24. A process for fabricating the composition of claim 16, comprising at least following steps,
(a) mixing at least a light emitting moiety,
with another material to get a reaction mixture;
(b) forming an outer layer onto the outermost surface of the light emitting moiety in the reaction mixture by reacting at least an anion source represented by chemical formula (Va) or chemical formula (Vb) with a metal cation precursor in a reaction mixture; 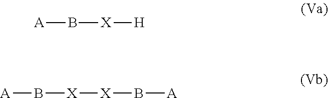
wherein
A is an organic group;
B is a connecting unit;
H is a hydrogen atom; and
X is an anchor group comprising an anion, capable to form a monolayer with the added metal cation derivable from the added metal cation precursor;
(c) cooling the reaction mixture from step (b),
wherein the reaction mixture in step (b) is kept at a temperature in the range from 80° C. to 200° C.,
(d) mixing a light emitting moiety obtained from step (c) with at least one reactive monomer or a mixture of two or more reactive monomers to from a composition.

25. The process of claim 24, the ratio of the total molar amount of the cation precursor to the total molar amount of the semiconducting nanoparticle in step (b) is in the range from 20:1 to 200000:1.

26. Formulation comprising at least a composition of claim 16, and at least one solvent selected from one or more members of the group consisting of aromatic, halogenated and aliphatic hydrocarbon solvents, ethers, esters, ionic liquids, alcohols and water.

27. Method for forming a layer comprising:
S1) providing the composition of claim 16 onto a substrate; and
S2) curing the composition.

28. A layer containing at least;
Xi) a light emitting moiety, comprising an outer layer containing a metal cation and a divalent anion; and
one or more types of organic moieties directly attached to the anion of the outer layer by covalent bond,
Xii) a polymer made from at least one reactive monomer or a mixture of two or more reactive monomers;
wherein said divalent anion of the outer layer is selected from Se²⁻, S²⁻, Te²⁻O²⁻ or a combination of thereof.

29. A color conversion device comprising at least a 1^{st} pixel partly or fully filled with the layer of claim 28 comprising at least a matrix material containing a light emitting moiety, and a bank comprising at least a polymer material.

30. An optical device containing at least one functional medium configured to modulate a light or configured to emit light, and the color conversion device of claim 29.
